(19) United States
(12) Patent Application Publication
(10) Pub. No.: US 2026/0040771 A1
(43) Pub. Date: Feb. 5, 2026

(54) DISPLAY DEVICE

(71) Applicant: LG Display Co., Ltd., Seoul (KR)

(72) Inventors: Yosup SIM, Seongnam-si (KR); Yongmin KIM, Anyang-si (KR); Seungpyo HONG, Busan (KR)

(73) Assignee: LG Display Co., Ltd., Seoul (KR)

(21) Appl. No.: 19/285,633

(22) Filed: Jul. 30, 2025

(30) Foreign Application Priority Data
Aug. 2, 2024 (KR) 10-2024-0103006

(51) Int. Cl. H10K 59/122; H10K 59/38; H10K 59/40; H10K 59/80; H10K 102/00

(52) U.S. Cl. CPC H10K 59/122; H10K 59/80515; H10K 59/80521; H10K 59/877; H10K 59/38; H10K 59/40; H10K 59/873; H10K 59/8792; H10K 2102/341

(57) ABSTRACT

A display device according to an exemplary embodiment of the present disclosure includes a planarization layer disposed above a substrate and including a protrusion portion. An anode is disposed on a top surface and a side surface of the protrusion portion. A bank is disposed to cover the anode except for the top surface of the protrusion portion, and an organic layer is disposed on the exposed portion of the anode. A cathode is disposed on the organic layer. The bank has a height that is equal to or less than the height of the top surface of the protrusion portion.

### CROSS-REFERENCE TO RELATED APPLICATIONS

This application claims the priority of Korean Patent Application No. 10-2024-0103006 filed on Aug. 2, 2024, in the Korean Intellectual Property Office, the disclosure of which is incorporated herein by reference.

### BACKGROUND

### Technical Field

The present disclosure relates to a display device.

### Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, an electroluminescent display device is a self-emitting display device so that a separate light source is not necessary, which is different from a liquid crystal display device. Therefore, the light emitting display device may be manufactured to have a light weight and a small thickness. Further, since the electroluminescent display device is driven at a low voltage so that it is advantageous not only in terms of power consumption, but also in terms of color implementation, a response speed, a viewing angle, a contrast ratio (CR). Therefore, it is expected to be utilized in various fields.

In such an electroluminescent display device, when a current supplies to the light emitting diode in a forward direction, electrons and holes move through a p-n junction between a positive electrode (anode) which supplies holes and a negative electrode (cathode) which supplies electrons and recombine with each other. In this case, the electrons and holes have less energy than when they are separated, and light corresponding to the energy difference that occurs at this time is emitted.

In contrast, when the anode and the cathode come into direct contact with each other without having an emission layer therebetween to cause a short-circuit, a potential difference is not applied to the emission layer so that the light emitting diode does not operate. In order to suppress this problem, a bank is interposed between the anode and the cathode of a non-emission area to ensure a space between the anode and the cathode.

### BRIEF SUMMARY

The disclosed display device features a structure in which a protrusion portion of the planarization layer corresponds to the emission area, and the height of the bank is equal to or less than that of the protrusion. This configuration removes the taper typically formed at the boundary of the emission region, resulting in a flatter deposition surface for the organic layer and the cathode. As a result, uniformity in the thickness of deposited layers is improved, electrical resistance in the cathode is reduced, and the likelihood of electrical discontinuities is minimized. Additionally, the flattened structure improves the emission path, which contributes to a wider viewing angle and more consistent luminance performance.

This configuration is particularly well suited for color on encapsulation structures. By minimizing the step height between emission and non-emission areas, the thickness of the organic encapsulation layer can be reduced without requiring additional photomasks or fabrication steps. This leads to improved optical characteristics, reduced material usage, and simplified processing, which are beneficial for both rigid and flexible display applications.

The structure also contributes to reduced power consumption by ensuring a more efficient emission path and minimizing electrical losses in the cathode. This supports improved manufacturing yield and reliability while aligning with environmental and sustainability objectives by decreasing energy demand and material waste during production.

Various embodiments of the present disclosure provide a display device in which degradation of a viewing angle luminance due to taper of the bank is suppressed.

Various embodiments of the present disclosure provide a display device in which increased resistance of a cathode and an open circuit due to the taper of the bank are improved.

Technical benefits of the present disclosure are not limited to the above-mentioned benefits, and other benefits, which are not mentioned above, can be clearly understood by those skilled in the art from the following descriptions.

In order to achieve the above-described benefits, according to an aspect of the present disclosure, a display device includes a planarization layer disposed above a substrate and including a protrusion portion, an anode disposed on a top surface and a side surface of the protrusion portion, a bank disposed to cover the anode except for the top surface of the protrusion portion, an organic layer disposed on the anode exposed by the bank, and a cathode disposed on the organic layer. The bank has a height which is equal to or lower than a height of the top surface of the protrusion portion.

According to another aspect of the present disclosure, a display device includes a planarization layer disposed above a substrate, a protrusion portion disposed on the planarization layer and protruding to correspond to an emission area, an anode disposed on a part of a top surface of the planarization layer and a top surface and a side surface of the protrusion portion, a bank disposed so as to cover the anode except for the top surface of the protrusion portion, an organic layer disposed on the anode exposed by the bank, and a cathode disposed on the organic layer. The bank has a height which is equal to or lower than a height of the top surface of the protrusion portion.

Other detailed matters of the exemplary embodiments are included in the detailed description and the drawings.

According to the present disclosure, a height of an emission unit is formed to be the same as the height of the bank to remove the taper of the bank, to ensure a light path, through implementing a wide viewing angle.

According to the present disclosure, as the height of the bank is reduced, the thickness of the product is reduced.

According to the present disclosure, the increased resistance of the cathode and the short-circuit due to the taper of the bank are improved to implement low power and improve the yield. In the case of the low power, it is possible to implement ESG (Environment/Social/Governance) by reducing greenhouse gas emissions by reducing the use of fossil fuels for power generation.

When the present disclosure is applied to the color on encapsulation (COE) technique, as the height of the bank is reduced, the thickness of the organic encapsulation layer is reduced by alleviating the step of the emission unit. Therefore, the usage of an organic material required to form the organic encapsulation layer is reduced to save the cost. Further, even though a COE structure with the same margin is applied, the viewing angle luminance is improved by the reduced thickness of the organic encapsulation layer.

According to the present disclosure, the above-described effects may be obtained without adding a mask and a process.

Other detailed matters of the exemplary embodiments are included in the detailed description and the drawings.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a view schematically illustrating a configuration of a display device according to exemplary embodiments of the present disclosure;

FIG. 2 is a plan view schematically illustrating a display panel of FIG. 1;

FIG. 3 is a perspective view illustrating a structure in which a touch panel is embedded in a display panel;

FIG. 4 is a view illustrating a pixel structure, in a display panel according to a first exemplary embodiment of the present disclosure;

FIG. 5 is a cross-sectional view taken along the line A-A′ of FIG. 4;

FIG. 6 is a view illustrating a pixel structure in a display panel of a comparative embodiment;

FIG. 7 is a view illustrating a pixel structure, in a display panel according to a second exemplary embodiment of the present disclosure;

FIG. 8 is a cross-sectional view taken along the line B-B′ of FIG. 7;

FIG. 9 is a view illustrating a cross-sectional structure, in a display panel according to a third exemplary embodiment of the present disclosure;

FIG. 10 is a view enlarging a part C of FIG. 9;

FIG. 11 is a view illustrating a part of a cross-section of a display panel of a comparative embodiment;

FIGS. 12A to 12F are cross-sectional views sequentially illustrating a part of a manufacturing process of a display panel of FIG. 9;

FIG. 13 is a view illustrating a cross-sectional structure, in a display panel according to a fourth exemplary embodiment of the present disclosure; and

FIG. 14 is a view illustrating a cross-sectional structure, in a display panel according to a fifth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

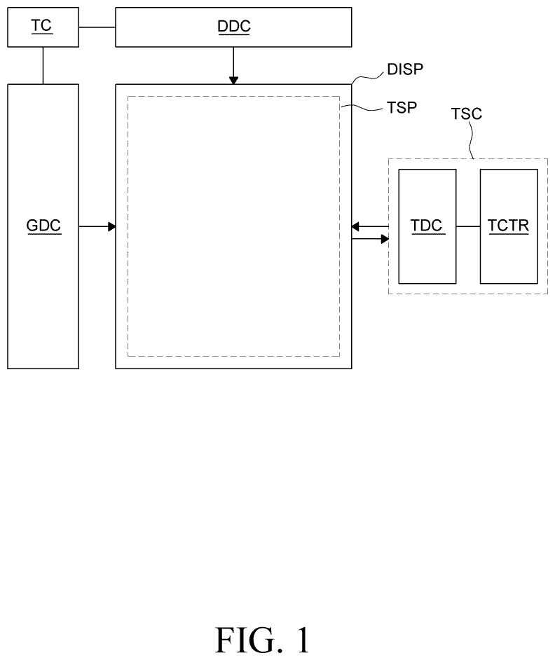

FIG. 1 is a view schematically illustrating a configuration of a display device according to exemplary embodiments of the present disclosure.

For example, FIG. 1 illustrates a schematic configuration of a display device in which a touch panel TSP according to exemplary embodiments of the present disclosure is embedded. However, the present disclosure is not limited thereto and a display device according to the exemplary embodiments of the present disclosure may not include a touch panel.

Referring to FIG. 1, the display device according to exemplary embodiments of the present disclosure may provide both a function for displaying images and a function for sensing a touch.

In order to provide an image displaying function, the display device according to the exemplary embodiments of the present disclosure may include a display panel DISP, a gate driving circuit GDC, a data driving circuit DDC, and a timing controller TC.

For example, in the display panel DISP, a plurality of data lines and a plurality of gate lines are disposed and a plurality of sub pixels defined by the plurality of data lines and the plurality of gate lines may be disposed.

The data driving circuit DDC drives a plurality of data lines and the gate driving circuit GDC drives a plurality of gate lines, and the timing controller TC may control an operation of the data driving circuit DDC and the gate driving circuit GDC.

Each of the data driving circuit DDC, the gate driving circuit GDC, and the timing controller TC may be implemented by one or more individual components. In some cases, two or more of the data driving circuit DDC, the gate driving circuit GDC, and the timing controller TC may be implemented to be integrated as one component. For example, the data driving circuit DDC and the timing controller TC may be implemented as one integrated chip (IC chip).

In order to provide a touch sensing function, the display device according to exemplary embodiments of the present disclosure may include a touch panel TSP and a touch sensing circuit TSC. The touch panel TSP includes a plurality of touch electrodes. The touch sensing circuit TSC supplies a touch driving signal to the touch panel TSP and detects a touch sensing signal from the touch panel TSP to sense the presence of a touch of a user or a touch position (touch coordinate) in the touch panel TSP based on the detected touch sensing signal.

For example, the touch sensing circuit TSC may include a touch driving circuit TDC and a touch controller TCTR. The touch driving circuit TDC supplies a touch driving signal to the touch panel TSP and detects a touch sensing signal from the touch panel TSP. The touch controller TCTR senses the presence of a touch of a user and/or a touch position in the touch panel TSP based on the touch sensing signal detected by the touch driving circuit TDC. The touch driving circuit TDC may include a first circuit part which supplies the touch driving signal to the touch panel TSP and a second circuit part which detects the touch sensing signal from the touch panel TSP.

For example, the touch driving circuit TDC and the touch controller TCTR may be implemented by separate components or in some cases, may be implemented to be integrated as one component.

For example, each of the data driving circuit DDC, the gate driving circuit GDC, and the touch driving circuit TDC may be implemented by one or more integrated circuits. From the viewpoint of electrical connection with the display panel DISP, the circuits may be implemented by a chip on glass (COG) type, a chip on film (COF) type, or a tape carrier package (TCP) type. Further, the gate driving circuit GDC may also be implemented by a gate in panel (GIP) type.

For example, each of circuit configurations DDC, GDC, and TC for display driving and circuit configurations TDC and TCTR for touch sensing may be implemented by one or more individual components. In some cases, one or more of circuit configurations DDC, GDC, and TC for display driving and one or more of circuit configurations TDC and TCTR for touch sensing are functionally integrated to be implemented by one or more components.

For example, the data driving circuit DDC and the touch driving circuit TDC may be implemented to be integrated in one or two or more integrated circuit chips. When the data driving circuit DDC and the touch driving circuit TDC are implemented to be integrated in two or more integrated circuit chips, each of two or more integrated circuit chips may have a data driving function and a touch driving function.

In the meantime, the display device according to the exemplary embodiments of the present disclosure may be various types such as a light emitting display device or a liquid crystal display device. Hereinafter, for the convenience of description, a light emitting display device will be described as an example of the display device. That is, even though the display panel DISP may be various types such as a light emitting display panel or a liquid crystal display panel, in the following description, for the convenience of description, a light emitting display panel will be described as an example of the display panel DISP.

Further, as it will be described below, the touch panel TSP may include a plurality of touch electrodes which is applied with a touch driving signal or detects a touch sensing signal and a plurality of touch routing lines which connects the plurality of touch electrodes to the touch driving circuit TDC.

The touch panel TSP may be provided at the outside of the display panel DISP. For example, the touch panel TSP and the display panel DISP may be separately manufactured and then combined. Such a touch panel TSP is called an external type or an add-on type.

In contrast, the touch panel TSP may be embedded in the display panel DISP. For example, when the display panel DISP is manufactured, a touch sensor structure such as a plurality of touch electrodes and a plurality of touch routing lines which configure the touch panel TSP may be formed together with a plurality of electrodes and signal lines for display driving.

Further, the touch panel TSP may be formed directly above an encapsulation unit of the display panel DISP. For example, the touch insulating film and the touch electrodes are patterned above the encapsulation unit and are connected to signal lines formed as electrodes for display driving to be driven. Hereinafter, for the convenience of description, an example that the touch panel TSP is formed directly above the encapsulation unit will be described.

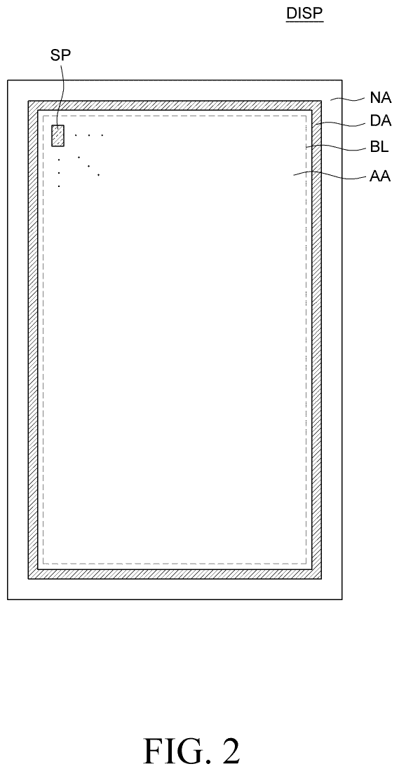

FIG. 2 is a plan view schematically illustrating a display panel of FIG. 1.

Referring to FIG. 2, the display panel DISP may include an active area AA in which images are displayed and a non-active area NA which is an outer area of an outer boundary line BL of the active area AA.

In the active area AA of the display panel DISP, a plurality of sub pixels SP for displaying images is disposed and various electrodes or signal lines for display driving are disposed.

Further, in the active area AA of the display panel DISP, a plurality of touch electrodes for touch sensing and a plurality of touch routing lines electrically connected thereto may be disposed. Accordingly, the active area AA may also be referred to as a touch sensing area which is capable of sensing the touch.

In the non-active area NA of the display panel DISP, link lines extending from various signal lines disposed in the active area AA or link lines which are electrically connected to various signal lines disposed in the active area AA, and pads which are electrically connected to the link lines may be disposed. The pads disposed in the non-active area NA may be bonded or electrically connected with the display driving circuit.

Further, in the non-active area NA of the display panel DISP, link lines extending from a plurality of touch routing lines disposed in the active area AA or link lines which are electrically connected to a plurality of touch routing lines disposed in the active area AA, and pads which are electrically connected to the link lines may be disposed. The pads disposed in the non-active area NA may be bonded or electrically connected with the touch driving circuit.

In the non-active area NA, a part of an outermost touch electrode, among a plurality of touch electrodes disposed in the active area AA, extends or one or more electrodes (touch electrodes) formed of the same material as the plurality of touch electrodes disposed in the active area AA may be further disposed.

For example, all the plurality of touch electrodes disposed in the display panel DISP may be present in the active area AA or some (for example, an outermost touch electrode) among the plurality of touch electrodes disposed in the display panel DISP may be present in the non-active area NA. Some (for example, an outermost touch electrode) among the plurality of touch electrodes disposed in the display panel DISP may be present over the active area AA and the non-active area NA.

Referring to FIG. 2, the display panel DISP according to the exemplary embodiments of the present disclosure may include a dam area DA having a dam for suppressing any layer (for example, the encapsulation unit in the display panel) in the active area AA from passing over the display panel DISP.

The dam area DA may be located at a boundary of the active area AA and the non-active area NA or at any one position of a non-active area NA which is an outer area of the active area AA.

A dam disposed in the dam area DA may be disposed to enclose all directions of the active area AA or disposed only at an outside of one or two or more parts of the active area AA.

The dam disposed in the dam area DA may have one pattern which is connected or two or more separated patterns. Further, in the dam area DA, only a primary dam may be disposed or two dams (primary dam and secondary dam) may be disposed, or three or more dams may also be disposed.

For example, in the dam area DA, in any one direction, only the primary dam is disposed and in the other direction, both the primary dam and the secondary dam may be disposed.

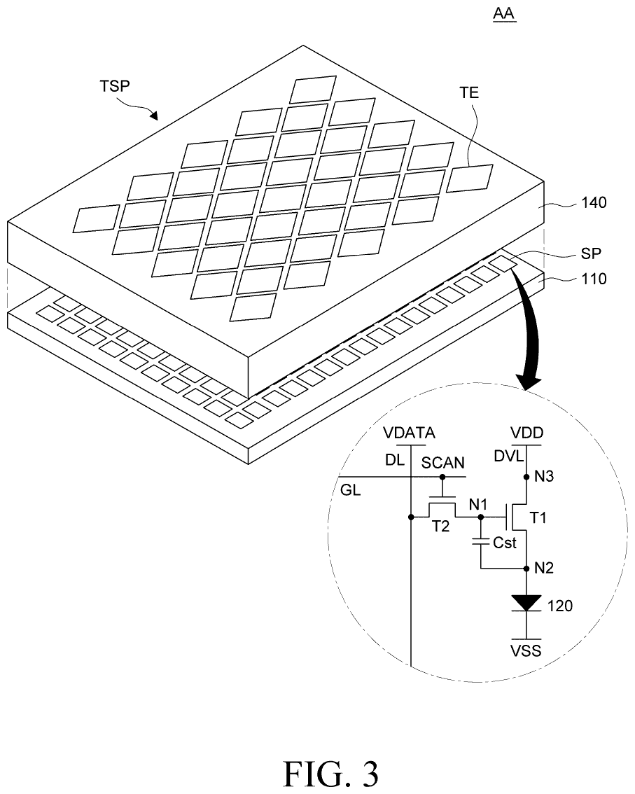

FIG. 3 is a perspective view illustrating a structure in which a touch panel is embedded in a display panel.

FIG. 3 is a perspective view illustrating a structure in which a touch panel is embedded in a display panel according to an exemplary embodiments of the present disclosure.

Referring to FIG. 3, for example, in the active area AA of the display panel (DISP in FIG. 2), a plurality of sub pixels SP may be disposed above the substrate 110.

Each sub pixel SP may include a light emitting diode 120, a first transistor T1 for driving the light emitting diode 120, a second transistor T2 for transmitting a data voltage VDATA to a first node N1 of the first transistor T1, and a storage capacitor Cst for maintaining a constant voltage for one frame.

For example, the first transistor T1 may include a first node N1 to which the data voltage VDATA is applied, a second node N2 which is electrically connected to the light emitting diode 120, and a third node N3 to which a driving voltage VDD is applied from a driving voltage line DVL. The first node N1 may be a gate node, the second node N2 may be a source node or a drain node, and the third node N3 may be a drain node or a source node. The first transistor T1 may also be referred to as a driving transistor which drives the light emitting diode 120.

The light emitting diode 120 may include a first electrode (for example, an anode), an emission layer, and a second electrode (for example, a cathode). The first electrode is electrically connected to the second node N2 of the first transistor T1 and the second electrode may be applied with a base voltage VSS.

The emission layer in the light emitting diode 120 may be configured by an organic material or an inorganic material.

For example, the second transistor T2 is controlled to be turned on or off by a scan signal SCAN applied through the gate line GL and may be electrically connected between the first node N1 of the first transistor T1 and the data line DL. Further, the second transistor T2 may be referred to as a switching transistor.

For example, when the second transistor T2 is turned on by the scan signal SCAN, the second transistor T2 may transmit the data voltage VDATA supplied from the data line DL to the first node N1 of the first transistor T1.

Further, the storage capacitor Cst may be electrically connected between the first node N1 and the second node N2 of the first transistor T1.

As illustrated in FIG. 3, each sub pixel SP may have a 2TIC structure including two transistors T1 and T2 and one capacitor Cst and in some cases, may further include one or more transistors or further include one or more capacitors.

The first transistor T1 and the second transistor T2 may be configured by an n-type transistor or a p-type transistor. As described above, in the display panel DISP, circuit elements such as a light emitting diode 120, two or more transistors T1 and T2, and one or more capacitors Cst may be disposed. The circuit element (specifically, the light emitting diode 120) is vulnerable to external moisture or oxygen so that an encapsulation unit 140 for suppressing the external moisture or oxygen from permeating the circuit element may be disposed on the display panel DISP.

The encapsulation unit 140 may be formed by one layer, or also formed by a plurality of layers.

In the meantime, in the display device according to the exemplary embodiments of the present disclosure, the touch panel TSP may be disposed above the encapsulation unit 140. For example, in the display device according to the exemplary embodiments of the present disclosure, a touch sensor structure, such as a plurality of touch electrodes TE which configures a touch panel TSP, may be disposed above the encapsulation unit 140.

Further, the display device according to the exemplary embodiments of the present disclosure may sense the touch based on capacitance formed in the touch electrode TE.

The display device according to the exemplary embodiments of the present disclosure employs a capacitance based touch sensing manner so that the touch is sensed by a mutual-capacitance based touch sensing manner or a self-capacitance based touch sensing manner.

For example, according to the mutual-capacitance based touch sensing manner, a plurality of touch electrodes TE may be classified into a driving touch electrode (a transmission touch electrode) to which a touch driving signal is applied and a sensing touch electrode (a reception touch electrode) which detects a touch sensing signal and forms a capacitance with the driving touch electrode.

In the case of the mutual-capacitance based touch sensing manner, the touch sensing circuit senses the presence of the touch and/or the touch coordinate based on the change in capacitance (mutual-capacitance) between the driving touch electrode and the sensing touch electrode depending on the presence of a pointer such as a finger or a pen.

According to the self-capacitance based touch sensing manner, each touch electrode TE may serve as both a driving touch electrode and a sensing touch electrode. For example, the touch sensing circuit applies a touch driving signal to one or more touch electrodes TE and detects a touch sensing signal by means of the touch electrode TE applied with the touch driving signal. The touch sensing circuit identifies the change in capacitance between a pointer such as a finger or a pen and the touch electrode TE based on the detected touch sensing signal to sense the presence of touch and/or the touch coordinate. In the self-capacitance based touch sensing manner, the driving touch electrode and the sensing touch electrode are not distinguished.

As described above, the display device according to the exemplary embodiments of the present disclosure may sense the touch by the mutual-capacitance based touch sensing manner or the self-capacitance based touch sensing manner. However, in the following description, for the convenience of description, it will be described that the display device performs mutual-capacitance based touch sensing and includes a touch sensor structure therefor, as an example.

Hereinafter, a configuration of a sub pixel will be described in detail with reference to the drawings.

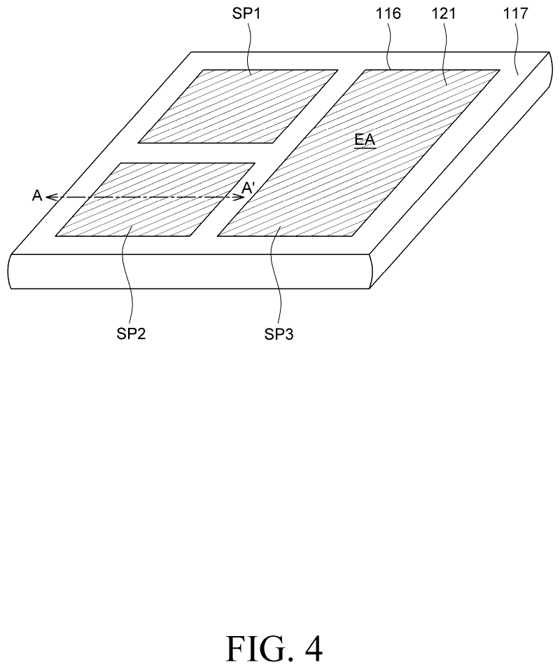

FIG. 4 is a view illustrating a pixel structure, in a display panel according to a first exemplary embodiment of the present disclosure.

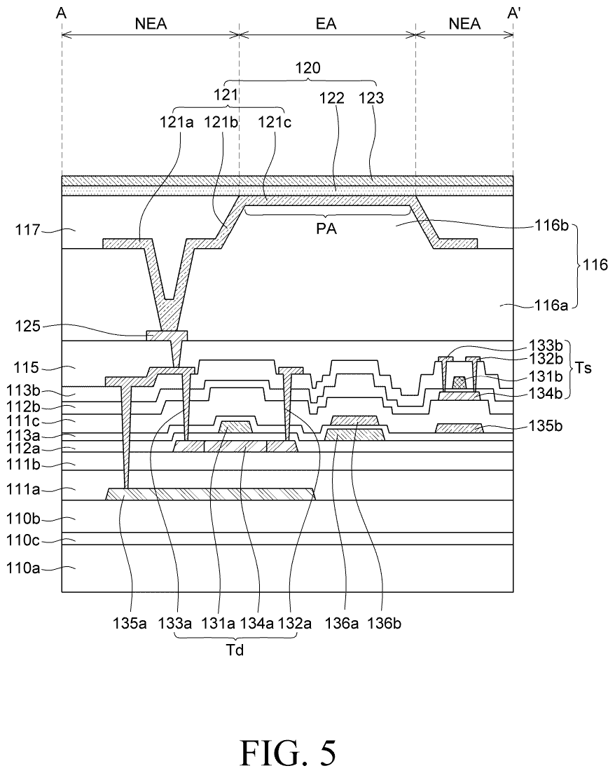

FIG. 5 is a cross-sectional view taken along the line A-A′ of FIG. 4.

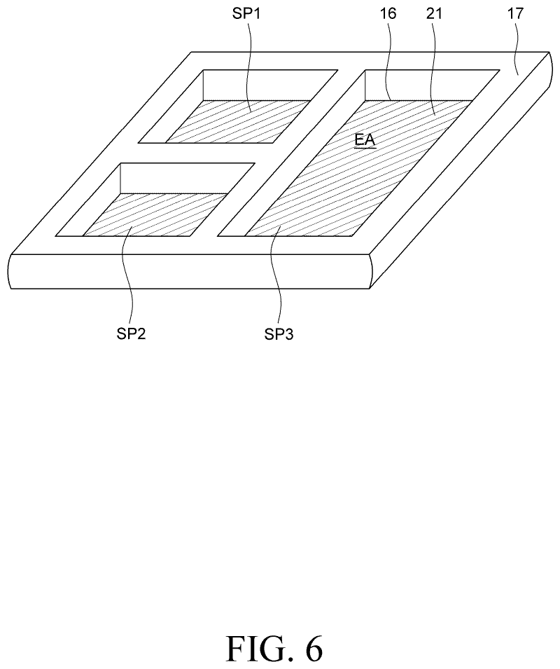

FIG. 6 is a view illustrating a pixel structure in a display panel of a comparative embodiment.

FIG. 4 shows a part of the display panel in which three sub pixels SP1, SP2, and SP3 are disposed as an example and shows a second planarization layer 116 and a bank 117 which define a protrusion area PA and an emission area EA as an example.

FIG. 5 illustrates a part of a cross-section of a second sub pixel SP2 of a display panel according to the first exemplary embodiment of the present disclosure.

Further, even though in FIG. 5, components above the light emitting diode 120 are not illustrated for the convenience of description, the present disclosure is not limited thereto and the present disclosure may include an encapsulation unit, a touch sensor layer and/or a color filter layer and a black matrix above the light emitting diode 120.

FIG. 6 illustrates a pixel structure of a display panel of a comparative embodiment in which the second planarization layer 16 does not have a protrusion portion so that a top surface has a bank 17 and a step.

Referring to FIG. 4, the display panel according to the first exemplary embodiment of the present disclosure may include a pixel area in which a plurality of sub pixels SP1, SP2, and SP3 is provided and a wiring area in which various signal lines are disposed.

A plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a polygonal shape such as a rectangular shape, but are not limited thereto and may have various shapes, such as a circle or an oval.

At this time, a shape of the sub pixels SP1, SP2, and SP3 may be defined by the shape of the third area of the anode 121, but it is not limited thereto.

In FIG. 4, it is illustrated that one first sub pixel Sp1, one second sub pixel SP2, and one third sub pixel SP3 are gathered to configure one pixel, but is not limited thereto. In one pixel, fourth white sub pixels may be added.

According to the first exemplary embodiment, the second planarization layer 116 has a protrusion portion 116b so that top surfaces of the protrusion portion 116b of the second planarization layer 116 and the bank 117 do not have a step and are substantially flat. The top surface of the protrusion portion 116b of the second planarization layer 116 may correspond to the third area 121c of the anode 121.

However, the present disclosure is not limited thereto and the protrusion portion 116b of the second planarization layer 116 may protrude more than the top surface of the bank 117 in consideration of the process margin or an error. In contrast, according to the comparative embodiment of FIG. 6, it is understood that the second planarization layer 16 does not have a protrusion portion so that the top surface of the second planarization layer 16, that is, the top surface of the anode 21 has a step with the top surface of the bank 17. In this case, the light path is partially blocked by the bank 17 and the bank 17 has a steep taper so that the cathode and the organic layer are formed with a relatively thin thickness on the side surface of the bank 17, which causes the increase of the resistance and open circuit of the cathode.

As described above, according to the present disclosure, a height of the emission unit is formed to be substantially equal to the height of the bank 117 to remove the taper of the bank 117 to ensure the light path and implement a wide viewing angle. Further, the increase of the resistance and the open circuit of the cathode 123 are improved to implement a low power and improve a yield.

Referring to FIG. 5, the driving transistor Td, the switching transistor Ts, and the light emitting diode 120 may be disposed above substrates 110a, 110b, and 110c. However, the present disclosure is not limited to the placement of the driving transistor Td and the switching transistor Ts of FIG. 5.

For example, the substrates 110a, 110b, and 110c may include a first substrate 110a, a second substrate 110b, and an interlayer insulating film 110c. The interlayer insulating film 110c may be disposed between the first substrate 110a and the second substrate 110b. However, the present disclosure is not limited thereto and a single layer of substrate may be used.

As described above, the substrates 110a, 110b, and 110c is configured by the first substrate 110a, the second substrate 110b, and the interlayer insulating film 110c to suppress permeation of the moisture. For example, the first substrate 110a and the second substrate 110b may be polyimide (PI) substrates, but are not limited thereto. Further, the substrates 110a, 110b, and 110c may use a flexible material to become flexible substrates. By using this, a foldable display panel which is foldable or bendable may be manufactured.

A plurality of transistors, such as a driving transistor Td or a switching transistor Ts, may be disposed above the substrates 110a, 110b, and 110c.

A multi-buffer layer 111a is disposed on the second substrate 110b and an active buffer layer 111b may be disposed on the multi-buffer layer 111a.

In the meantime, a first light shielding layer 135a may be disposed above the second substrate 110b. However, it is not limited thereto and the first light shielding layer 135a may be disposed on the multi-buffer layer 111a. Further, in some cases, the first light shielding layer 135a may be omitted.

The first light shielding layer 135a may serve as a light shield.

The multi-buffer layer 111a may be disposed on the first light shielding layer 135a.

The active buffer layer 111b may be disposed above the multi-buffer layer 111a.

A first active layer 134a of the driving transistor Td may be disposed above the active buffer layer 111b.

A first gate insulating film 112a may be disposed on the first active layer 134a.

Further, a first gate electrode 131a of the driving transistor Td may be disposed on the first gate insulating film 112a.

Further, for example, a gate material layer 136a may be disposed on the first gate insulating film 112a in a position different from a forming position of the driving transistor Td. For example, the gate material layer 136a may be a first storage electrode, but is not limited thereto.

The first interlayer insulating film 113a may be disposed on the first gate electrode 131a.

A metal layer 136b may be disposed on the first interlayer insulating film 113a. For example, the material layer 136b may be a second storage electrode, but is not limited thereto.

In this case, the metal layer 136b may configure the storage capacitor together with the gate material layer 136a, but is not limited thereto.

Further, for example, a second light shielding layer 135b may be disposed on the first interlayer insulating film 113a in a position different from a forming position of the metal layer 136b.

The buffer layer 111c may be disposed on the metal layer 136b and the second light shielding layer 135b.

A second active layer 134b of the switching transistor Ts may be disposed on the buffer layer 111c.

A second gate insulating film 112b may be disposed on the second active layer 134b.

Further, a second gate electrode 131b of the switching transistor Ts may be disposed on the second gate insulating film 112b.

The second interlayer insulating film 113b may be disposed on the second gate electrode 131b.

A first source electrode 132a and a first drain electrode 133a of the driving transistor Td may be disposed on the second interlayer insulating film 113b. Further, a second source electrode 132b and a second drain electrode 133b of the switching transistor Ts may be disposed on the second interlayer insulating film 113b.

At this time, for example, the first source electrode 132a and the first drain electrode 133a may be electrically connected to one side and the other side of the first active layer 134a through contact holes provided in the second interlayer insulating film 113b, the second gate insulating film 112b, the buffer layer 111c, the first interlayer insulating film 113a, and the first gate insulating film 112a.

Further, for example, a part of the first drain electrode 133a may be electrically connected to one side of the first light shielding layer 135a through contact holes provided in the second interlayer insulating film 113b, the second gate insulating film 112b, the buffer layer 111c, the first interlayer insulating film 113a, the first gate insulating film 112a, the active buffer layer 111b, and the multi-buffer layer 111a.

Further, for example, the second source electrode 132b and the second drain electrode 133b may be electrically connected to one side and the other side of the second active layer 134b, through contact holes provided in the second interlayer insulating film 113b and the second gate insulating film 112b, respectively.

A part of the first active layer 134a which overlaps the first gate electrode 131a is a channel region. For example, one of the first source electrode 132a and the first drain electrode 133a is connected to one side of the channel region in the first active layer 134a and the other one may be connected to the other side of the channel region in the first active layer 134a.

Further, a part of the second active layer 134b which overlaps the second gate electrode 131b is a channel region. For example, one of the second source electrode 132b and the second drain electrode 133b is connected to one side of the channel region in the second active layer 134b and the other one may be connected to the other side of the channel region in the second active layer 134b.

Even though it is not illustrated, a protection film may be disposed on the first source electrode 132a, the first drain electrode 133a, the second source electrode 132b, and the second drain electrode 133b.

The planarization layers 115 and 116 may be disposed above the first source electrode 132a, and the first drain electrode 133a and the second source electrode 132b and the second drain electrode 133b. For example, the planarization layers 115 and 116 may include a first planarization layer 115 and a second planarization layer 116.

The first planarization layer 115 may be disposed on the protection film.

The connection electrode 125 may be disposed on the first planarization layer 115.

For example, the connection electrode 125 may be electrically connected to one of the first source electrode 132a and the first drain electrode 133a through a contact hole provided in the first planarization layer 115.

The second planarization layer 116 may be disposed on the connection electrode 125.

The second planarization layer 116 may be configured by an organic material, such as acrylic-based resin or epoxy-based resin, and for example, may be configured by photo acryl (PAC). For the convenience of description, the second planarization layer 116 may be referred to as a planarization layer.

For example, the second planarization layer 116 may include a bottom layer 116a which is disposed in the entire emission area EA and non-emission area NEA on the first planarization layer 115 and a protrusion portion 116b which is disposed on the bottom layer 116a and protrudes so as to correspond to the emission area EA of the sub pixel.

Referring to FIG. 4, in the plan view, the emission area EA or the protrusion area PA may have approximately (or entirely) a polygonal shape, such as a rectangle. However, it is not limited thereto and may have various shapes, such as a circle or an oval.

The protrusion portion 116b may have a top surface and a side surface.

The top surface of the protrusion portion 116b is a surface located on the top of the second planarization layer 116 and is substantially parallel to the second substrate 110b. The top surface of the protrusion portion 116b may correspond to a protrusion area PA.

A side surface of the protrusion portion 116b may extend from the top surface of the protrusion portion 116b. For example, the side surface of the protrusion portion 116b may have a taper at a predetermined angle. In FIG. 5, an example that the top surface and the side surface of the protrusion portion 116b having straight line shapes meet to form a vertex is illustrated, but the present disclosure is not limited thereto and the side surface of the protrusion portion 116b may have a gentle curved line.

The top surface of the protrusion portion 116b may have approximately (or entirely) a polygonal shape, such as a rectangle, substantially the same as the protrusion area PA, in the plan view. However, as described above, the present disclosure is not limited thereto and may have various shapes, such as a circle or an oval.

For example, the anode 121 may be disposed on a part of the top surface of the bottom layer 116a of the second planarization layer 116 and a top surface and a side surface of the protrusion portion 116b. For example, the anode 121 may be disposed in the protrusion area PA, the side surface of the protrusion portion 116b, and a part of the top surface of the bottom layer 116a. Further, for example, the anode 121 disposed in the protrusion area PA may be in contact with the top surface of the protrusion portion 116b of the second planarization layer 116.

For example, the anode 121 may include a first area 121a and a second area 121b. The first area 121a is disposed on a part of the top surface of the bottom layer 116a of the second planarization layer 116 and has a surface substantially parallel to a surface of the second substrate 110b. The second area 121b extends from the first area 121a and has a surface which has a predetermined angle with respect to the second substrate 110b. The second area 121b of the anode 121 may correspond to the side surface of the protrusion portion 116b. Therefore, the second area 121b of the anode 121 may be referred to as a side surface of the anode 121.

The anode 121 may include a third area 121c which extends from the second area 121b and has a surface which is substantially parallel to a surface of the second substrate 110b. The third area 121c may correspond to a top surface of the protrusion portion 116b. Further, the third area 121c of the anode 121 may correspond to the protrusion area PA.

As described above, in one sub pixel, the second planarization layer 116 may include at least one contact hole which is spaced apart from the protrusion area PA and the driving transistor Td and the anode 121 are electrically connected through the contact hole. For example, the driving transistor Td and the first area 121a of the anode 121 may be connected through the contact hole.

The bank 117 may be disposed while covering the first area 121a and the second area 121b of the anode 121.

The bank 117 may cover the first area 121a and the second area 121b of the anode 121. In contrast, the bank 117 may expose the third area 121c of the anode 121. For example, the bank 117 may have a height which is equal to or lower than the height of the protrusion portion 116b of the second planarization layer 116. At this time, the height may refer to a height from the first substrate 110a to a top surface of the bank 117 or the protrusion portion 116b of the second planarization layer 116.

Accordingly, in the first exemplary embodiment of the present disclosure, the taper of the bank 117 may be substantially removed. A step is substantially removed between the top surface of the bank 117 and the top surface of the protrusion portion 116b of the second planarization layer 116 so that the taper of the bank 117 may be removed. That is, the top surface of the bank 117 and the top surface of the protrusion portion 116b of the second planarization layer 116 may form a substantially flat surface.

A part of the bank 117 corresponding to an emission area EA of the sub pixel may be open.

For example, a part of the bank 117 corresponding to an emission area EA of each sub pixel may be removed (open). At this time, the emission area EA has a width and an area larger than those of the protrusion area PA, that is, the top surface of the protrusion portion 116b of the planarization layer 116. Further, for example, in the plan view, the emission area EA may have a polygonal shape, such as a rectangle, but is not limited thereto. The emission area EA of the present disclosure may have various shapes, such as a circle or an oval.

An emission image which is formed by the emission area EA may have a shape corresponding to a shape of the emission area EA. At this time, when a shape of an arbitrary component corresponds to a shape of the other component, it means that the shape of the arbitrary component has the same shape as the other component, or has the same shape, but has a different size, or a shape of the arbitrary component is formed by transferring the shape of the other component by an arbitrary method. Accordingly, it is understood that the shape of the emission image formed by the emission area EA is substantially a shape of the emission area EA which is transferred by light emitted from the organic layer 122 located in the emission area EA. According to the present disclosure, as the taper of the bank 117 is removed, the emission image may have a size larger than the shape of the emission area EA.

Next, the bank 117 may include a top surface, a side surface, and a bottom surface.

For example, the top surface of the bank 117 may be a surface located on the top of the bank 117 and is substantially parallel to the second substrate 110b. Further, the top surface of the bank 117 may be substantially parallel to the top surface of the protrusion portion 116b of the second planarization layer 116.

Further, the top surface of the bank 117 may correspond to the non-emission area NEA.

A side surface of the bank 117 may be a surface extending from the top surface of the bank 117 to a side surface. The side surface of the bank 117 may have a predetermined taper angle. The side surface of the bank 117 may correspond to the side surface of the protrusion portion 116b of the second planarization layer 116.

Further, for example, the bottom surface of the bank 117 may correspond to a surface which abuts with the anode 121 in the first area 121a of the anode 121.

The side surface and the bottom surface of the bank 117 may correspond to the non-emission area NEA.

The protrusion area PA provided in the protrusion portion 116b of the second planarization layer 116 may have a width and an area smaller than those of the emission area EA which is defined by the bank 117. Accordingly, the protrusion area PA may be located in the emission area EA.

For example, the third area 121c of the anode 121 may be exposed by the emission area EA.

The bank 117 may be formed of a PI based material, but is not limited thereto.

Further, the bank 117 may be formed of a black material. For example, the bank 117 may be configured such that the black pigment is dispersed in an organic material, but is not limited thereto and as long as the bank has a black color, the bank may be configured by an arbitrary black material. Further, for example, the organic material may be cardo-based polymer or polymer including epoxy acrylate, but is not limited thereto. As the bank 117 includes a black material, reflection of external light, specifically, irregular reflection caused when the bank 117 is formed of a transparent material, may be reduced.

Further, the bank 117 may be configured by a plurality of layers. For example, the first bank layer is formed of a black material and the second bank layer disposed thereabove may be formed of a transparent material. Further, the second bank layer may include a spacer (not illustrated). The spacer may serve to suppress damage generated on the configurations disposed on the substrates 110a, 110b, and 110c caused when the mask used during the deposition of the organic layer 122 is in contact with the substrates 110a, 110b, and 110c. When the spacer is included, the height of the spacer in the non-emission area NEA is higher than that of the protrusion portion 116b of the second planarization layer 116 in the emission area EA, but is not limited thereto.

An inside surface of the bank 117 may have a polygonal shape, such as a rectangle, substantially similar to the edge of the emission area EA, but is not limited thereto. For example, the inside surface of the bank 117 of the present disclosure may have various shapes, such as a circle or an oval.

For example, the organic layer 122 may be disposed on the bank 117 and the top surface of the third area 121c of the anode 121. At this time, in FIG. 5, it is illustrated that the organic layer 122 is disposed over the emission area EA and the non-emission area NEA as an example, but the present disclosure is not limited thereto. Therefore, the organic layer 122 may be disposed only in the emission area EA or may be disposed in a part of the emission area EA and the non-emission area NEA.

The cathode 123 is disposed on the organic layer 122.

The light emitting diode 120 may be configured by the anode 121, the organic layer 122, and the cathode 123. A part of the light emitting diode 120 corresponding to the third area 121c of the anode 121 in which the light is actually emitted may be referred to as an emission unit.

The emission area EA may be formed by the light emitting diode 120 provided in the emission unit.

An encapsulation unit may be disposed above the above-described light emitting diode 120.

The encapsulation layer may have a single layer structure or a multi-layered structure. For example, the encapsulation unit may include a first encapsulation layer, a second encapsulation layer, and a third encapsulation layer.

A touch sensor layer may be disposed above the above-described encapsulation unit.

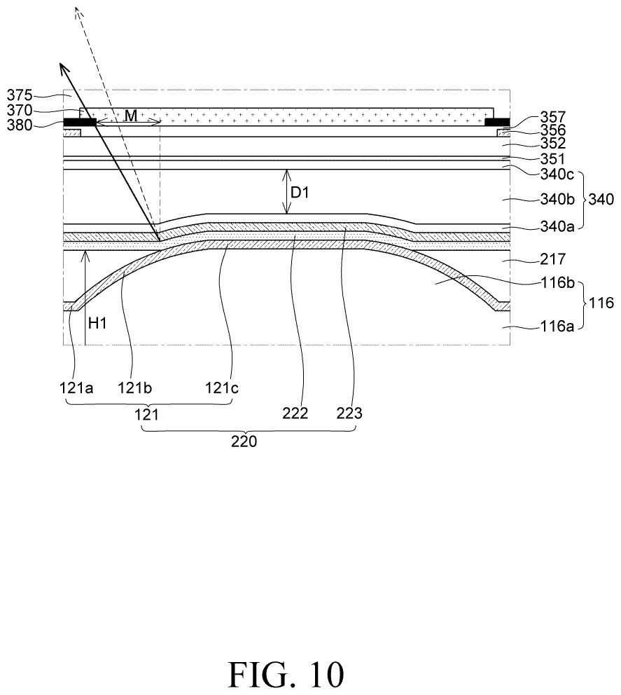

As described above, according to the first exemplary embodiment of the present disclosure, the height of the emission unit is formed to be substantially equal to the height of the bank 117 to remove the taper of the bank 117, thereby implementing the wide viewing angle by ensuring the light path. Further, as the height of the bank 117 is reduced, the thickness of the product is reduced. A detailed description with regard to this will be described below with reference to FIG. 10.

Further, according to the first exemplary embodiment of the present disclosure, the increase of the resistance and the open circuit of the cathode 123 due to the taper of the bank 117 are improved to implement the low power and improve the yield. In the case of the low power, it is possible to implement ESG (Environment/Social/Governance) by reducing greenhouse gas emissions by reducing the use of fossil fuels for power generation.

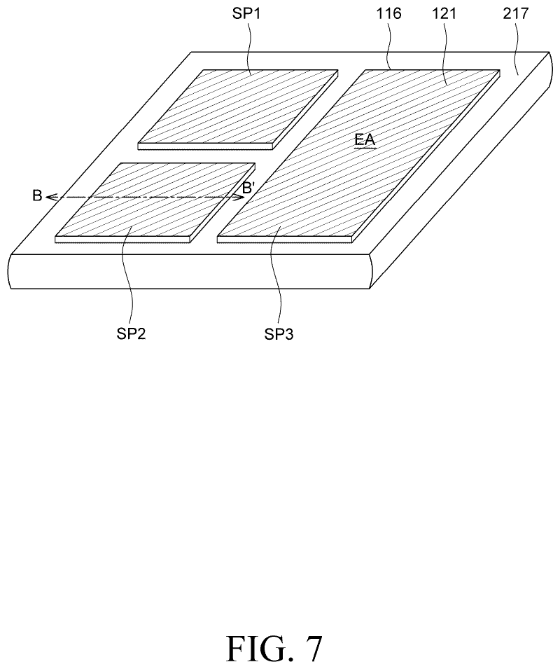

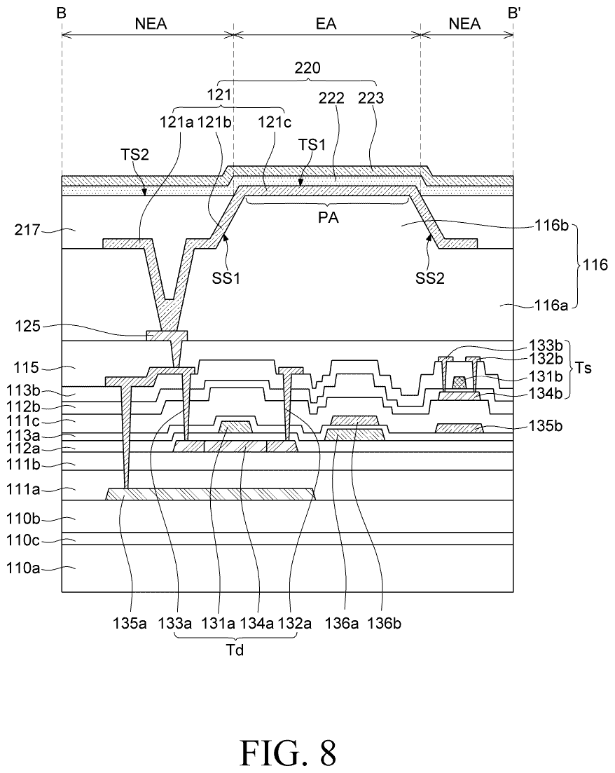

In the meantime, according to the present disclosure, the protrusion portion 116b of the second planarization layer 116 further protrudes more than the top surface of the bank 117 by taking into account the process margin or error, which will be described in more detail with reference to FIGS. 7 and 8.

FIG. 7 is a view illustrating a pixel structure of a display panel according to a second exemplary embodiment of the present disclosure.

FIG. 8 is a cross-sectional view taken along the line B-B′ of FIG. 7.

FIG. 7 shows a part of the display panel in which three sub pixels SP1, SP2, and SP3 are disposed as an example and shows a second planarization layer 116 and a bank 217 which define a protrusion area PA and an emission area EA as an example.

FIG. 8 illustrates a part of a cross-section of a second sub pixel SP2 of a display panel according to the second exemplary embodiment of the present disclosure.

Further, even though in FIG. 8, components above the light emitting diode 120 are not illustrated for the convenience of description, the present disclosure is not limited thereto and the present disclosure may include an encapsulation unit, a touch sensor layer and/or a color filter layer and a black matrix above the light emitting diode 120.

The second exemplary embodiment of FIGS. 7 and 8 are substantially the same as the first exemplary embodiment of FIGS. 4 to 6 described above, except that the protrusion portion 116b of the second planarization layer 116 protrudes more than the top surface of the bank 217 so that a redundant description will be omitted. Here, the description for the same reference numeral may refer to FIGS. 1 to 6.

Referring to FIG. 7, in the display panel according to the second exemplary embodiment of the present disclosure, a plurality of first sub pixels SP1, second sub pixels SP2, and third sub pixels SP3 are disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a polygonal shape such as a rectangular shape, but are not limited thereto and may have various shapes, such as a circular shape or an oval shape.

According to the second exemplary embodiment, the second planarization layer 116 has a protrusion portion 116b and the bank 217 has a height smaller than the protrusion portion 116b of the second planarization layer 116. This is caused by the process margin or error so that the end of the bank 217 may be disposed over the taper of the protrusion portion 116b of the second planarization layer 116. Therefore, the step of the top surfaces of the protrusion portion 116b of the second planarization layer 116 and the bank 217 may be alleviated. The top surface of the protrusion portion 116b of the second planarization layer 116 may correspond to the third area 121c of the anode 121.

As described above, according to the present disclosure, a height of the emission unit is formed to be substantially equal to the height of the bank 217 to remove the taper of the bank 217 to ensure the light path and implement a wide viewing angle. Further, the increase of the resistance and the open circuit of the cathode 223 are improved to implement a low power and improve a yield.

Referring to FIG. 8, the driving transistor Td, the switching transistor Ts, and the light emitting diode 120 may be disposed above substrates 110a, 110b, and 110c. The description of the driving transistor Td and the switching transistor Ts may refer to the first exemplary embodiment of the present disclosure described above.

The second planarization layer 116 may be disposed above the first planarization layer 115.

For example, the second planarization layer 116 may include a bottom layer 116a which is disposed in the entire emission area EA and non-emission area NEA on the first planarization layer 115 and a protrusion portion 116b which is disposed on the bottom layer 116a and protrudes so as to correspond to the emission area EA of the sub pixel.

Referring to FIG. 7, in the plan view, the emission area EA or the protrusion area PA may have approximately (or entirely) a polygonal shape, such as a rectangle. However, it is not limited thereto and may have various shapes, such as a circle or an oval.

The protrusion portion 116b may have a top surface and a side surface.

The top surface of the protrusion portion 116b is a surface located on the top of the second planarization layer 116 and is substantially parallel to the second substrate 110b. The top surface of the protrusion portion 116b may correspond to a protrusion area PA.

A side surface of the protrusion portion 116b may extend from the top surface of the protrusion portion 116b.

The top surface of the protrusion portion 116b may have approximately (or entirely) a polygonal shape, such as a rectangle, substantially the same as the protrusion area PA, in the plan view. However, as described above, the present disclosure is not limited thereto and may have various shapes, such as a circle or an oval.

For example, the anode 121 may be disposed on a part of the top surface of the bottom layer 116a of the second planarization layer 116 and a top surface and a side surface of the protrusion portion 116b.

For example, the anode 121 may include a first area 121a and a second area 121b. The first area 121a is disposed on a part of the top surface of the bottom layer 116a of the second planarization layer 116 and has a surface substantially parallel to a surface of the second substrate 110b. The second area 121b extends from the first area 121a and has a surface which has a predetermined angle with respect to the second substrate 110b. For example, the second area 121b of the anode 121 may correspond to the side surface of the protrusion portion 116b.

The anode 121 may include a third area 121c which extends from the second area 121b has a surface which is substantially parallel to a surface of the second substrate 110b. The third area 121c may correspond to a top surface of the protrusion portion 116b. Further, the third area 121c of the anode 121 may correspond to the protrusion area PA.

The bank 217 may be disposed while covering the first area 121a and the second area 121b of the anode 121. At this time, the end of the bank 217 according to the second exemplary embodiment of the present disclosure may be disposed over the taper of the protrusion portion 116b of the second planarization layer 116. Accordingly, the bank 217 may not cover a part of the second area 121b of the anode 121.

As described above, the bank 217 according to the second exemplary embodiment of the present disclosure may expose a part of the second area 121b of the anode 121 and the third area 121c. For example, the bank 217 of the second exemplary embodiment of the present disclosure may have a height lower than that of the protrusion portion 116b of the second planarization layer 116.

Accordingly, in the second exemplary embodiment of the present disclosure, the taper of the bank 217 may be substantially removed. As the bank 217 has a height lower than that of the protrusion portion 116b of the second planarization layer 116, the taper of the bank 217 may be removed.

A part of the bank 217 corresponding to an emission area EA of the sub pixel may be open. In this case, the width and the area of the emission area EA may be increased as compared with the first exemplary embodiment. As the end of the bank 217 is disposed over the taper of the protrusion portion 116b of the second planarization layer 116, the width and the area of the emission area EA may be increased.

The bank 217 may include a top surface, a side surface, and a bottom surface.

For example, the top surface of the bank 217 is a surface located on the top of the bank 217 and is substantially parallel to the second substrate 110b. Further, the top surface of the bank 217 is substantially parallel to the top surface of the protrusion portion 116b of the second planarization layer 116.

Further, the top surface of the bank 217 may correspond to the non-emission area NEA.

A side surface of the bank 217 may extend from the top surface of the bank 217.

Further, for example, the bottom surface of the bank 217 may correspond to a surface which abuts with the anode 121 in the first area 121a of the anode 121.

The side surface and the bottom surface of the bank 217 may correspond to the non-emission area NEA.

Further, the bank 117 may be formed of a black material. For example, the bank 117 may be configured such that the black pigment is dispersed in an organic material, but is not limited thereto and as long as the bank has a black color, the bank may be configured by an arbitrary black material. Further, for example, the organic material may be cardo-based polymer or polymer including epoxy acrylate, but is not limited thereto. As the bank 117 includes a black material, reflection of external light, specifically, irregular reflection caused when the bank 117 is formed of a transparent material, may be reduced.

Further, the bank 117 may be configured by a plurality of layers. For example, the first bank layer is formed of a black material and the second bank layer disposed thereabove may be formed of a transparent material. Further, the second bank layer may include a spacer (not illustrated). The spacer may serve to suppress damage generated on the configurations disposed on the substrates 110a, 110b, and 110c caused when the mask used during the deposition of the organic layer 122 is in contact with the substrates 110a, 110b, and 110c. When the spacer is included, the height of the spacer in the non-emission area NEA is higher than that of the protrusion portion 116b of the second planarization layer 116 in the emission area EA, but is not limited thereto.

The protrusion area PA provided in the protrusion portion 116b of the second planarization layer 116 may have a width and an area smaller than those of the emission area EA which is defined by the bank 217. Accordingly, the protrusion area PA may be located in the emission area EA.

For example, a part of the second area 121b and the third area 121c of the anode 121 may be exposed by the emission area EA.

For example, the organic layer 222 may be disposed on the bank 217 and a part of the second area 121b, and the top surface of the third area 121c of the anode 121.

The cathode 223 may be disposed on the organic layer 222.

The light emitting diode 220 may be configured by the anode 121, the organic layer 222, and the cathode 223.

An encapsulation unit may be disposed above the light emitting diode 220.

A touch sensor layer may be disposed above the encapsulation unit.

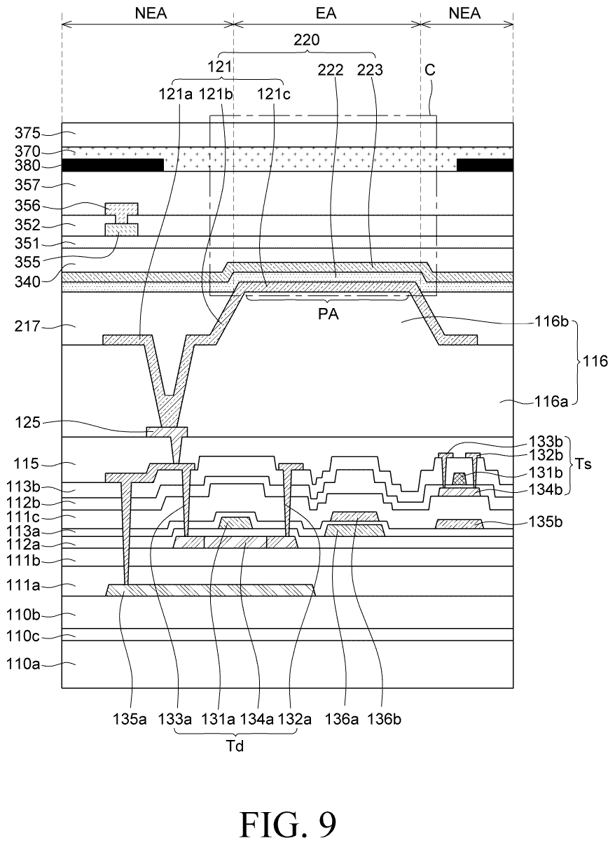

In the meantime, the present disclosure may be applied to a color on encapsulation (COE) technique in which the color filter layer is disposed above the encapsulation unit in a state in which the top surfaces of the emission unit and the bank 217 are flat, which will be described in detail with reference to FIGS. 9 to 11.

FIG. 9 is a view illustrating a cross-sectional structure of a display panel according to a third exemplary embodiment of the present disclosure.

FIG. 10 is a view enlarging a part C of FIG. 9.

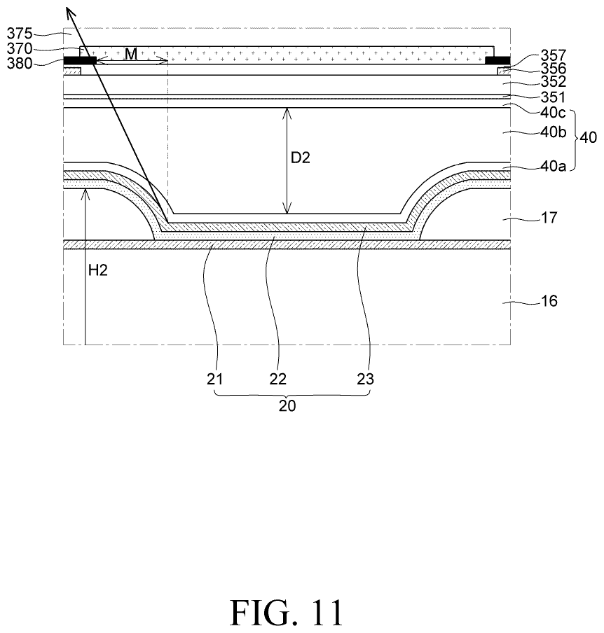

FIG. 11 is a view illustrating a part of a cross-section of a display panel of a comparative embodiment.

FIG. 9 illustrates a part of a cross-section of a sub pixel of a display panel according to a third exemplary embodiment of the present disclosure as an example.

FIG. 10 enlarges an emission unit of FIG. 9 and configurations therearound. Further, FIG. 11 enlarges an emission unit of the comparative embodiment and configurations therearound. Further, in FIGS. 10 and 11, for the sake of convenience, configurations below the second planarization layers 116 and 16 are omitted.

The third exemplary embodiment of the present disclosure of FIGS. 9 and 10 are substantially the same as the second exemplary embodiment of FIGS. 7 and 8 described above except that only the COE technique in which the color filter layer 370 is disposed above the encapsulation unit 340 is applied. However, the other configurations are substantially the same so that a redundant description will be omitted. Here, the description for the same reference numeral may refer to FIGS. 1 to 8.

Referring to FIGS. 9 and 10, the second planarization layer 116 including a protrusion portion 116b may be disposed above the first planarization layer 115.

For example, the second planarization layer 116 may include a bottom layer 116a which is disposed in the entire emission area EA and non-emission area NEA on the first planarization layer 115 and a protrusion portion 116b which is disposed on the bottom layer 116a and protrudes so as to correspond to the emission area EA of the sub pixel.

In FIG. 9, an example that the top surface and the side surface of the protrusion portion 116b having straight line shapes meet to form a vertex is illustrated, but the present disclosure is not limited thereto and as illustrated in FIG. 10, the side surface of the protrusion portion 116b may have a gentle curved line. In this case, a portion that a top surface and a side surface of the protrusion portion 116b meet may maintain a curved shape. Further, even though the bank 217 has a height lower than the protrusion portion 116b of the second planarization layer 116, the organic layer 222 deposited thereon may be continuously formed without having a scam or being disconnected.

For example, the anode 121 may be disposed on a part of the top surface of the bottom layer 116a of the second planarization layer 116 and a top surface and a side surface of the protrusion portion 116b.

For example, the anode 121 may include a first area 121a and a second area 121b. The first area 121a is disposed on a part of the top surface of the bottom layer 116a of the second planarization layer 116 and has a surface substantially parallel to a surface of the second substrate 110b. The second area 121b extends from the first area 121a and has a surface which has a predetermined angle with respect to the second substrate 110b. The anode 121 may include a third area 121c which extends from the second area 121b and has a surface which is substantially parallel to a surface of the second substrate 110b.

The bank 217 may be disposed while covering the first area 121a and the second area 121b of the anode 121. At this time, the end of the bank 217 according to the third exemplary embodiment of the present disclosure may be disposed over the taper of the protrusion portion 116b of the second planarization layer 116. In this case, the bank 217 has a height lower than the protrusion portion 116b of the second planarization layer 116, but is not limited thereto and the bank 217 may have the same height as the protrusion portion 116b of the second planarization layer 116.

As described above, the bank 217 according to the third exemplary embodiment of the present disclosure may expose a part of the second area 121b and the third area 121c of the anode 121.

A part of the bank 217 corresponding to an emission area EA of the sub pixel may be open.

For example, a part of the second area 121b and the third area 121c of the anode 121 may be exposed by the emission area EA.

For example, the organic layer 222 may be disposed on the bank 217 and a part of the second area 121b, and the top surface of the third area 121c of the anode 121.

The cathode 223 may be disposed on the organic layer 222.

In the meantime, the encapsulating unit 340 may be disposed above the light emitting diode 220.

The light emitting diode 220 may react to external moisture and oxygen due to a characteristic of the organic material of the organic layer 222 to cause dark-spot or pixel shrinkage. In order to suppress this problem, the encapsulation unit 340 may be disposed above the cathode 223.

The encapsulation unit 340 may be configured by a first inorganic insulating film 340a, a foreign material compensation layer 340b, and a second inorganic insulating film 340c, but is not limited thereto.

The first inorganic insulating film 340a may be disposed above the substrates 110a, 110b, and 110c in which the cathode 223 is disposed to be the most adjacent to the light emitting diode 220.

For example, the first inorganic insulating film 340a is configured by an inorganic insulating material on which low-temperature deposition is allowed, such as silicon nitride (SiNx), silicon oxide (SiOx), silicon oxynitride (SiON), or aluminum oxide (Al₂O₃). The first inorganic insulating film 340a is deposited under a low temperature atmosphere so that the damage of the organic layer 222 including an organic material vulnerable to the high temperature atmosphere during the deposition may be suppressed.

The foreign material compensation layer 340b may be disposed to have a smaller area than the first inorganic insulating film 340a and may be configured to expose both ends of the first inorganic insulating film 340a. The foreign material compensation layer 340b may be formed of an organic insulating material, such as acrylic resin, epoxy resin, polyimide, polyethylene, or silicon oxy carbon (SiOC). The foreign material compensation layer 340b may be referred to as an organic encapsulation layer.

In the meantime, when the foreign material compensation layer 340b is formed by an inkjet method, one or more dams may be disposed in a boundary area of the non-active area and the active area or a dam area corresponding to a partial area in the non-active area may be disposed. In such a dam area, a primary dam adjacent to the active area and a secondary dam adjacent to the pad unit may be disposed.

When a liquid type foreign material compensation layer 340b is dropped in the active area, one or more dams disposed in the dam area suppress the liquid type foreign material compensation layer 340b from collapsing in the direction of the non-active area to invade the pad unit.

The primary dam and/or secondary dam may be configured as a single layer or a multi-layered structure.

The foreign material compensation layer 340b including an organic material may be located only on an inner surface of the primary dam.

The second inorganic insulating film 340c may be disposed so as to cover a top surface and a side surface of each of the first inorganic insulating film 340a and the foreign material compensation layer 340b. The second inorganic insulating film 340c may serve to minimize or block the permeation of the external moisture or oxygen into the first inorganic insulating film 340a and the foreign material compensation layer 340b.

The second inorganic encapsulation layer 340c may be formed of an inorganic insulating material, such as silicon nitride (SiNx), silicon oxide (SiOx), silicon oxynitride (SiON), or aluminum oxide (Al₂O₃).

A touch buffer film 351 may be disposed on the encapsulation unit 340.

A bridge pattern 355 may be disposed on the touch buffer film 351. However, it is not limited thereto and a touch electrode (or a touch line) may be disposed on the touch buffer film 351.

The touch buffer film 351 may be located between the bridge pattern 355 and the encapsulation unit 340.

The bridge pattern 355 may be disposed above the encapsulation unit 340 without having the touch buffer film 351.

The bridge pattern 355 may have a single layer or multi-layered structure formed of a metal having strong corrosion resistance and acid resistance, such as aluminum (Al), titanium (Ti), copper (Cu), or molybdenum (Mo).

The touch insulating film 352 may be disposed on the bridge pattern 355.

For example, the touch insulating film 352 may use an organic film or an inorganic film which may be formed by a low temperature process. When the organic film is used for the touch insulating film 352, after coating the organic film above the substrates 110a, 110b, and 110c, the organic film is cured at a temperature of 1000° C. or lower to form the touch insulating film 352 to suppress the damage of the organic layer 222 vulnerable to the high temperature. When the inorganic film is used for the touch insulating film 352, in order to suppress the damage of the organic layer 222 vulnerable to the high temperature, a low temperature chemical vapor deposition process and a washing process are repeated at least twice to form the touch insulating film 352 with a multi-layered structure.

A partial area of the touch insulating film 352 is selectively removed to form a touch contact hole to expose a part of the bridge pattern 355.

A touch electrode (or a touch line) 356 may be disposed on the touch insulating film 352. However, it is not limited thereto and the bridge pattern may be disposed on the touch insulating film 352.

For example, the touch electrode 356 may be electrically connected to the bridge pattern 355 through the touch contact hole.

Further, the touch planarization layer 357 may be disposed on the touch electrode 356, but is not limited thereto and the touch planarization layer may be omitted.

A black matrix 380 may be disposed on the touch planarization layer 357.

The black matrix 380 may be located above the touch electrode 356.

The black matrix 380 may be located so as to correspond to the non-emission area NEA.

The color filter layer 370 may be disposed in the non-emission area NEA and the emission area EA above the black matrix 380.

For example, the color filter layer 370 may include a red color filter layer, a green color filter layer, and a blue color filter layer, but is not limited thereto and may further include a white color filter layer.

The black matrix 380 may be disposed on the boundary of color filter layer 370 with different colors. Therefore, the black matrix 380 may define a sub pixel area. Sub pixel areas defined by the black matrix 380 may be a red sub pixel area, a green sub pixel area, and a blue sub pixel area. Further, the sub pixel area may further include a white sub pixel area. That is, an area in which the red color filter layer may be disposed corresponds to a red sub pixel area, an area in which the green color filter layer may be disposed corresponds to a green sub pixel area, and an area in which a blue color filter layer may be disposed corresponds to a blue sub pixel area. Further, an area in which a white color filter layer may be disposed corresponds to a white sub pixel area.

For example, in the area in which the red color filter layer is disposed, red light is emitted, in the area in which the green color filter layer is disposed, green light is emitted, in the area in which the blue color filter layer is disposed, blue light is emitted, and in the area in which the white color filter layer is disposed, white light may be emitted

An overcoat layer 375 may be disposed above the color filter layer 370.

In the meantime, according to the present disclosure, as the bank 217 has a height equal to or lower than that of the protrusion portion 116b of the second planarization layer 116, the taper of the bank 217 may be removed. Accordingly, the light path is ensured to implement the wide viewing angle (see FIG. 10). In contrast, according to the comparative embodiment of FIG. 11, it is understood that the second planarization layer 16 does not have a protrusion portion so that the top surface of the second planarization layer 16, that is, the top surface of the anode 21 has a step with the top surface of the bank 17. In this case, a part of the light path is blocked by the bank 17. That is, light which travels at a high angle is blocked by the bank 17 so that the viewing angle luminance is lowered.

Further, in the case of the present disclosure, the height H1 of the bank 217 is lowered to alleviate the step of the emission unit to reduce the thickness D1 of the encapsulation unit 340, that is, the foreign material compensation layer 340b of the encapsulation unit 340. In contrast, according to the comparative embodiment of FIG. 11, a step is formed by the top surface of the anode 21 and the top surface of the bank 17 so that the thickness D2 of the foreign material compensation layer 40b of the encapsulation unit 40 is increased in consideration of the step of the emission unit. For reference, reference numerals 40a and 40c refer to a first inorganic insulation film and a second inorganic insulation film.

As described above, according to the present disclosure, the thickness D1 of the foreign material compensation layer 340b is reduced so that even though the COE structure of the same margin M is applied, the light path (a solid line arrow of FIG. 10) expands more than a light path (a dotted line arrow of FIG. 10) of the comparative embodiment. As a result, the viewing angle luminance is improved to implement a wide viewing angle.

Further, according to the comparative embodiment of FIG. 11, as the bank 17 has a taper, a step coverage of the organic layer 22 and the cathode 23 deposited on the taper is lowered so that the organic layer and the cathode are vertically deposited. In this case, the organic layer 22 and the cathode 23 are deposited to have a thickness smaller than the other part and are deposited to be thinner as the taper of the bank 17 is larger, so that the resistance increases and the open circuit of the cathode 23 may occur (see the part E of FIG. 11).

In contrast, according to the present disclosure, even though there is no taper of the bank 217 and the bank 217 has a height lower than the protrusion portion 116b of the second planarization layer 116, there is almost no step between the top surface of the bank 217 and the top surface of the protrusion portion 116b of the second planarization layer 116. Therefore, the organic layer 222 and the cathode 223 are deposited with a uniform thickness in the entire area. Accordingly, the low power is implemented by improving the resistance increase and the open circuit of the cathode 123 and the yield is improved.

Further, according to the present disclosure, as the height of the bank 217 is reduced, the thickness of the final product is reduced.

In the meantime, the present disclosure has an advantage in that the above-described effects are achieved without adding the mask and the process, which will be described in detail with reference to the drawings.

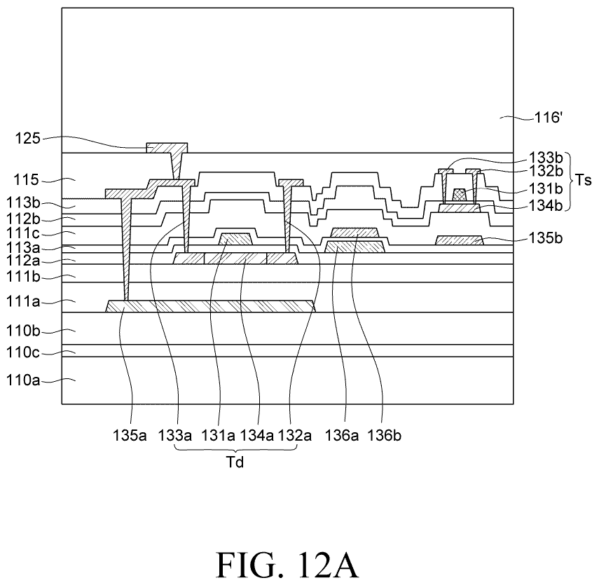

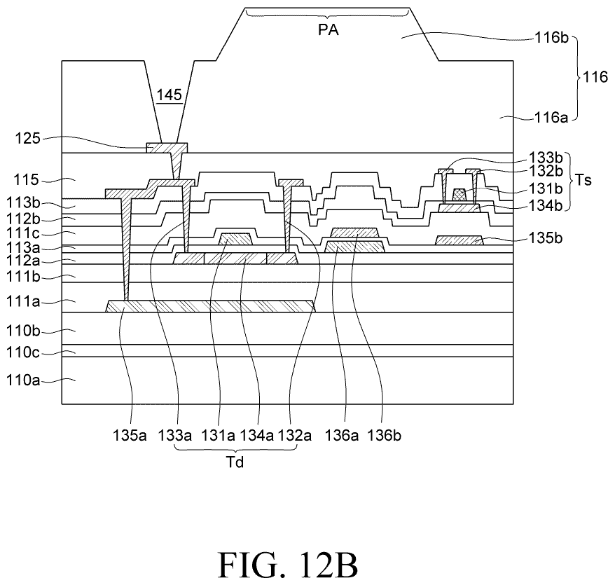

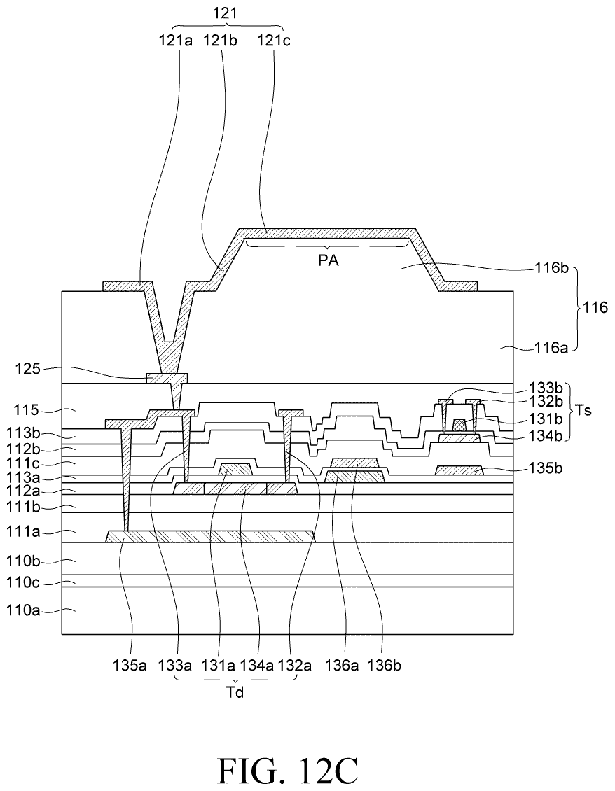

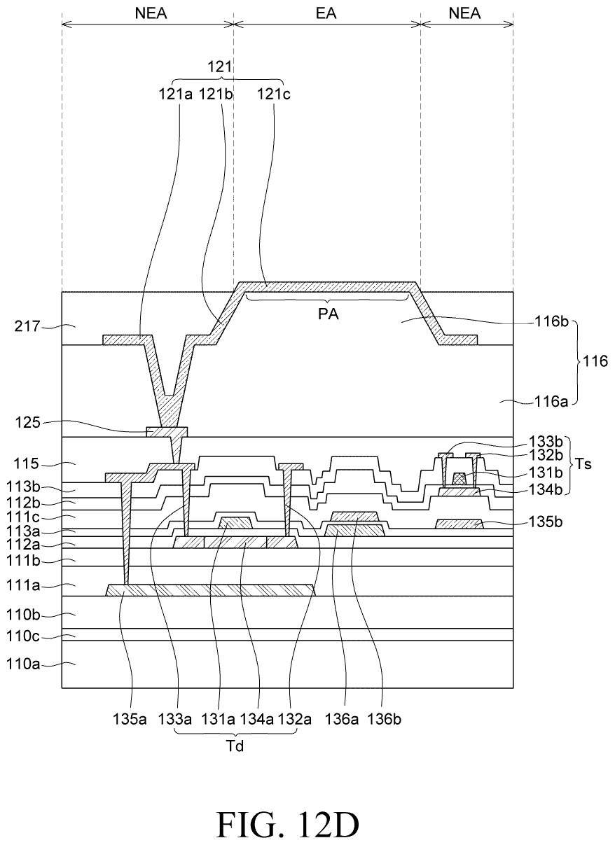

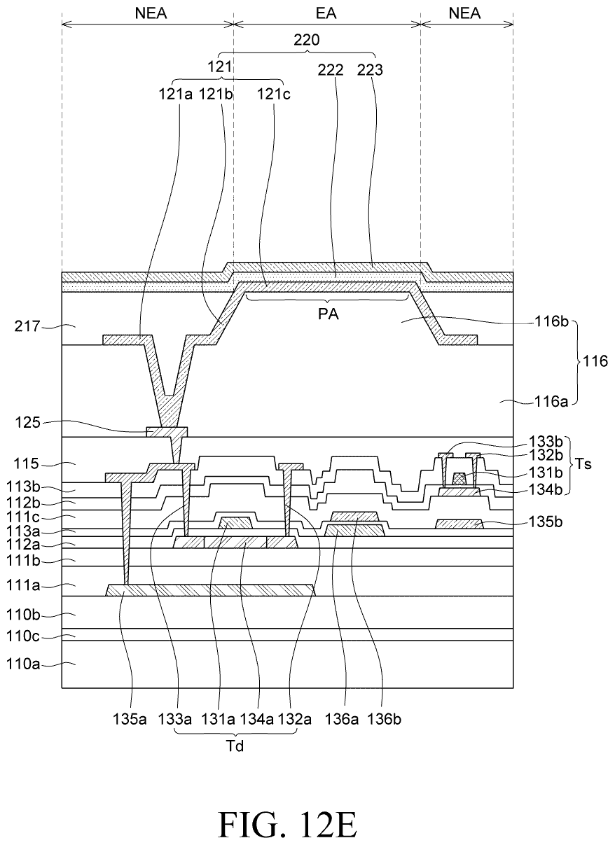

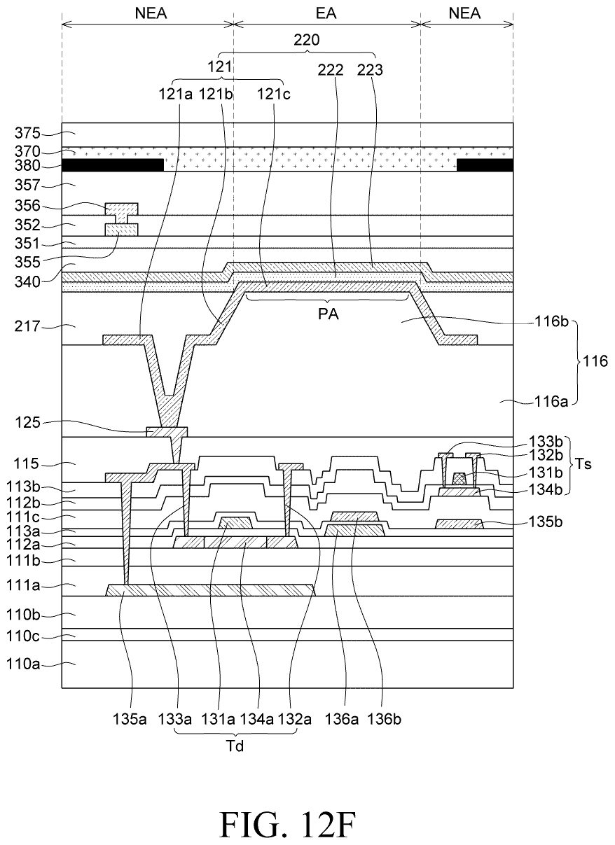

FIGS. 12A to 12F are cross-sectional views sequentially illustrating a part of a manufacturing process of a display panel of FIG. 9.

Referring to FIG. 12A, the driving transistor Td and the switching transistor Ts may be disposed above substrates 110a, 110b, and 110c.

A protection film and/or a first planarization layer 115 may be formed above the driving transistor Td and the switching transistor Ts.

Thereafter, the connection electrode 125 may be disposed on the first planarization layer 115.

For example, the connection electrode 125 may be electrically connected to one of the first source electrode 132a and the first drain electrode 133a through a contact hole provided in the first planarization layer 115. However, the present disclosure is not limited thereto and the anode is directly connected without having the connection electrode.

Thereafter, an insulating layer 116′ may be formed on the connection electrode 125.

The insulating layer 116′ may be formed by an organic material, such as acrylic-based resin or epoxy-based resin, and for example, may be formed by photo acryl (PAC).

Thereafter, referring to FIG. 12B, a partial area of the insulating layer 116′ is selectively removed by the mask process to form a contact hole 145 which exposes a part of the connection electrode 125.

At this time, the other part of the insulating layer 116′ is removed by the same mask process to form a second planarization layer 116. The second planarization layer 116 may include a bottom layer 116a which is disposed in the entire emission area and non-emission area on the first planarization layer 115 and a protrusion portion 116b which is disposed on the bottom layer 116a and protrudes so as to correspond to the emission area of the sub pixel.

As described above, according to the present disclosure, when the contact hole 145 is formed, the second planarization layer 116 including the protrusion portion 116b is patterned by the same mask process.

The protrusion portion 116b may have a top surface and a side surface.

The top surface of the protrusion portion 116b may be a surface located on the top of the second planarization layer 116 and is substantially parallel to the second substrate 110b. The top surface of the protrusion portion 116b may correspond to a protrusion area PA. A side surface of the protrusion portion 116b may extend from the top surface of the protrusion portion 116b.

Referring to FIG. 12C, the anode 121 may be formed on a part of the top surface of the bottom layer 116a of the second planarization layer 116 and a top surface and a side surface of the protrusion portion 116b.

For example, the anode 121 may include a first area 121a and a second area 121b. The first area 121a is disposed on a part of the top surface of the bottom layer 116a of the second planarization layer 116 and has a surface substantially parallel to a surface of the second substrate 110b. The second area 121b extends from the first area 121a and has a surface which has a predetermined angle with respect to the second substrate 110b. The anode 121 may include a third area 121c which extends from the second area 121b and has a surface which is substantially parallel to a surface of the second substrate 110b.

The first area 121a of the anode 121 may be electrically connected to the driving transistor Td through the contact hole 145 and the connection electrode 125.

Next, referring to FIG. 12D, the bank 217 may be formed while covering the first area 121a and the second area 121b of the anode 121.

According to the third exemplary embodiment of the present disclosure, the bank 217 is formed to have a height which is equal to or lower than the height of the protrusion portion 116b of the second planarization layer 116.

The end of the bank 217 according to the third exemplary embodiment of the present disclosure is disposed over the taper of the protrusion portion 116b of the second planarization layer 116 to ensure the process margin. Therefore, the bank 217 may not cover a part of the second area 121b of the anode 121, but the present disclosure is not limited thereto and the bank 217 may cover the entire second area 121b of the anode 121. In this case, the top surfaces of the protrusion portion 116b of the second planarization layer 116 and the bank 217 do not have a step, but may be substantially flat.

Thereafter, referring to FIG. 12E, the organic layer 222 may be formed on the bank 217 and a part of the second area 121b, and the top surface of the third area 121c of the anode 121.

Thereafter, the cathode 223 may be disposed on the organic layer 222.

Thereafter, referring to FIG. 12F, the encapsulation unit 340 may be formed above the light emitting diode 220.

A touch sensor layer configured by a touch buffer film 351, a bridge pattern 355, a touch insulating film 352, a touch electrode 356, and a touch planarization layer 357 may be formed above the encapsulation unit 340.

The black matrix 380 and the color filter layer 370 may be formed above the touch sensor layer.

An overcoat layer 375 may be disposed above the color filter layer 370.

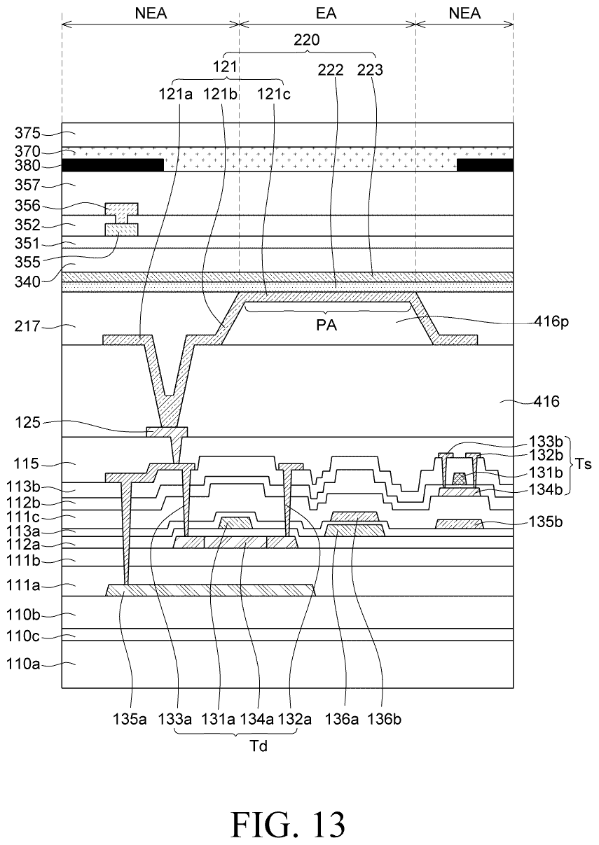

In the meantime, according to the present disclosure, the second planarization layer and the protrusion portion are separately formed, which will be described in detail with reference to FIG. 13.

FIG. 13 is a view illustrating a cross-sectional structure of a display panel according to a fourth exemplary embodiment of the present disclosure.

A fourth exemplary embodiment of the present disclosure of FIG. 13 is substantially the same as the third exemplary embodiment of FIG. 9 except that a second planarization layer 416 and a protrusion portion 416p are separately configured, but the other configurations are substantially the same. Therefore, a redundant description will be omitted. Here, the description for the same reference numeral may refer to FIGS. 1 to 9.

Referring to FIG. 13, a second planarization layer 416 may be disposed above a first planarization layer 115.

In the second planarization layer 416, a top surface excluding a contact hole which exposes the connection electrode 125 may be flat.

A protrusion portion 416p which protrudes so as to correspond to the emission area EA of the sub pixel may be disposed above the second planarization layer 416.

The protrusion portion 416p may have a top surface and a side surface.

The top surface of the protrusion portion 416p may be a surface which is substantially parallel to the second planarization layer 416. The top surface of the protrusion portion 416p may correspond to a protrusion area PA.

A side surface of the protrusion portion 416p may extend from the top surface of the protrusion portion 416p.

The protrusion portion 416p may be configured by a material different from that of the second planarization layer 416, but is not limited thereto and may be configured by the same material.

The anode 121 may be disposed on a part of the top surface of the second planarization layer 416 and a top surface and a side surface of the protrusion portion 416p.

The anode 121 of the fourth exemplary embodiment may include a first area 121a and a second area 121b. The first area 121a is disposed on a part of the top surface the second planarization layer 416 and has a surface substantially parallel to a surface of the second planarization layer 416. The second area 121b extends from the first area 121a to be disposed on the side surface of the protrusion portion 416p and has a surface which has a predetermined angle with respect to the second planarization layer 416. The anode 121 may include a third area 121c which extends from the second area 121b to be disposed on the protrusion portion 416p and has a surface which is substantially parallel to a surface of the second planarization layer 416.

The bank 217 may be disposed while covering the first area 121a and the second area 121b of the anode 121. For example, the bank 217 may have a height which is equal to or lower than the height of the protrusion portion 416p.

For example, the organic layer 222 may be disposed on the bank 217 and the top surface of the third area 121c of the anode 121.

The cathode 223 may be disposed on the organic layer 222.

The encapsulation unit 340 as described above and the touch sensor layer and/or the color filter layer 370 and the black matrix 380 may be disposed above the cathode 223.

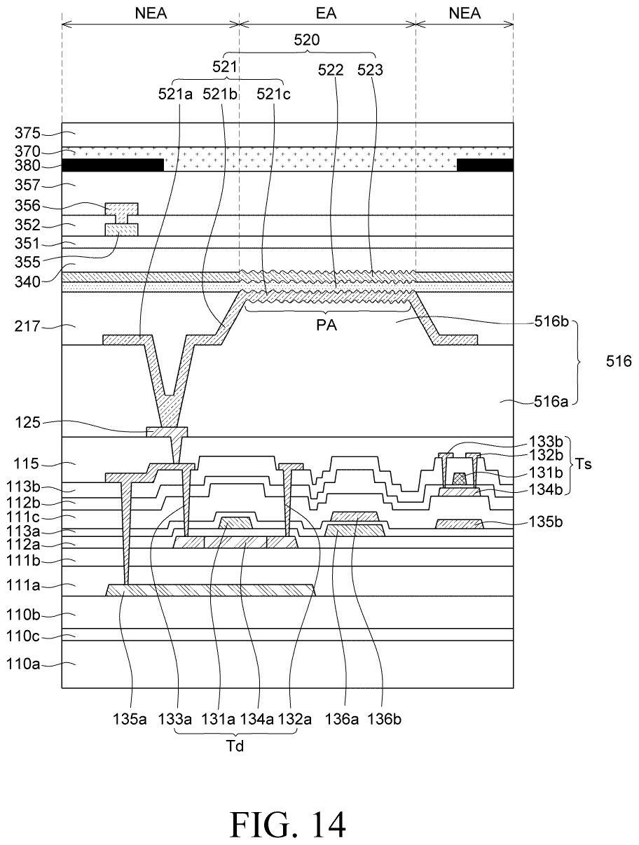

In the meantime, according to the present disclosure, the emission unit is formed with an uneven structure to improve the luminous efficiency, which will be described in detail with reference to FIG. 14.

FIG. 14 is a view illustrating a cross-sectional structure of a display panel according to a fifth exemplary embodiment of the present disclosure.

A fifth exemplary embodiment of the present disclosure of FIG. 14 is different from the third exemplary embodiment of FIG. 9 described above in that the emission unit is configured with an uneven structure, but other configurations are substantially the same so that a redundant description will be omitted. Here, the description for the same reference numeral may refer to FIGS. 1 to 14.

Referring to FIG. 14, a second planarization layer 516 may be disposed above a first planarization layer 115.

For example, the second planarization layer 516 may include a bottom layer 516a which is disposed in the entire emission area EA and non-emission area NEA on the first planarization layer 115 and a protrusion portion 516b which is disposed on the bottom layer 516a and protrudes so as to correspond to the emission area EA of the sub pixel.

The protrusion portion 516b may have a top surface and a side surface.

The top surface of the protrusion portion 516b is a surface located on the top of the second planarization layer 516 and is substantially parallel to the second substrate 110b. The top surface of the protrusion portion 516b may correspond to a protrusion area PA and have a concave and convex uneven structure.

A side surface of the protrusion portion 516b may extend from the top surface of the protrusion portion 516b.

For example, the anode 521 may be disposed on a part of the top surface of the bottom layer 516a of the second planarization layer 516 and a top surface and a side surface of the protrusion portion 516b.

For example, the anode 521 may include a first area 521a and a second area 521b. The first area 521a is disposed on a part of the top surface of the bottom layer 516a of the second planarization layer 516 and has a surface substantially parallel to a surface of the second substrate 110b. The second area 521b extends from the first area 521a and has a surface which has a predetermined angle with respect to the second substrate 110b.

The anode 521 may include a third area 521c which extends from the second area 521b to have a surface which is substantially parallel to a surface of the protrusion portion 516b of the second planarization layer 516.

The third area 521c of the anode 521 may have a concave and convex uneven structure corresponding to the shape of the top surface of the protrusion portion 516b.

The bank 217 may be disposed while covering the first area 521a and the second area 521b of the anode 521. For example, the bank 217 may have a height which is equal to or lower than the height of the protrusion portion 516b.

For example, the organic layer 522 may be disposed on the bank 217 and the top surface of the third area 521c of the anode 521.

Further, for example, the organic layer 522 may have a concave and convex uneven structure corresponding to the shape of the top surface of the protrusion portion 516b.

The cathode 523 may be disposed on the organic layer 522.

Further, for example, the cathode 523 may have a concave and convex uneven structure corresponding to the shape of the top surface of the protrusion portion 516b.

For example, the concave and convex uneven structures of the anode 521, the organic layer 522, and the cathode 523 may be micro lenses, but are not limited thereto.

As described above, according to the fifth exemplary embodiment of the present disclosure, when a predetermined voltage is applied between the anode 521 and the cathode 523, holes and electrons supplied from the anode 521 and the cathode 523 are transported to the organic layer 522 to form exciton. When the exciton is shifted from an excited state to the ground state, light is generated. Further, light generated in the organic layer 522 passes through the cathode 523 to be emitted to the outside to implement an arbitrary image. At this time, the micro lenses are formed in the protrusion portion 516b, the anode 521, the organic layer 522, and the cathode 523 to change a traveling path of light which is not extracted to the outside by the total reflection which is repeated in the organic layer to the outside, to improve a light extraction efficiency.

Further, the micro lenses of the protrusion portion 516b, the anode 521, the organic layer 522, and the cathode 523 are disposed in the entire protrusion area PA corresponding to the emission area EA. The entire emission area EA is used for the micro lens to maximize the light extraction efficiency.

The encapsulation unit 340 as described above and the touch sensor layer and/or the color filter layer 370 and the black matrix 380 may be disposed above the light emitting diode 520.

The exemplary embodiments of the present disclosure can also be described as follows:

According to an aspect of the present disclosure, there is provided a display device. The display device includes a substrate, over which a planarization layer 116 is disposed. A protrusion portion 116b may be formed on the planarization layer 116, and this protrusion portion may have a first side surface SS1, a second side surface SS2 opposite the first side surface SS1, and a top surface TS1 extending between the two side surfaces (see for example, FIG. 8). A first electrode 121 may be deposited such that it extends continuously along the top surface TS1, the first side surface SS1, and the second side surface SS2 of the protrusion portion. A bank 217 may be formed adjacent to the protrusion portion, the bank including a top surface TS2. An organic layer 222 may be disposed on the first electrode 121, and a second electrode 223 may be disposed on the organic layer 222. In some embodiments, the top surface TS2 of the bank is substantially co-planar with the top surface TS1 of the protrusion portion. This configuration provides a flat upper surface for uniform organic layer deposition and improved encapsulation planarity.

In one embodiment, the top surface TS2 of the bank and the top surface TS1 of the protrusion portion may terminate at substantially the same vertical level such that they are flush with one another. The flush alignment of these surfaces minimizes discontinuity across the upper surface of the emission region, which facilitates uniform deposition of subsequent layers and improves light extraction characteristics.

In another embodiment, the protrusion portion and the planarization layer may be integrally formed from the same material. For example, the planarization layer may be patterned by etching or photolithography to define a raised region that serves as the protrusion portion. Forming the protrusion integrally from the planarization layer simplifies the fabrication process and ensures material compatibility and uniform surface energy characteristics during deposition.

In some configurations, the bank may define a lateral opening that corresponds to an emission area located above the protrusion portion. The bank may surround the protrusion on multiple sides while leaving an aperture above the top surface of the protrusion portion. This arrangement allows for selective patterning of light-emitting materials and improved definition of pixel boundaries.

According to certain embodiments, the bank may cover at least a portion of the side surfaces of the first electrode while leaving the top surface of the protrusion portion exposed. This configuration ensures that the emission area remains accessible for deposition of the organic layer, while the side surfaces are shielded by the bank to prevent undesired leakage or electrical interference between adjacent pixels.

In alternative embodiments, the top surface of the bank is not co-planar with the top surface of the protrusion portion. Specifically, the top surface of the bank lies below the top surface of the protrusion portion. This height differential creates a step profile that can facilitate light redirection and optical confinement in certain display architectures, such as those with color-on-encapsulation layers.

As described above, even in non-coplanar configurations, the protrusion portion may still be formed integrally with the planarization layer from the same material. The planarization layer may be selectively patterned to define raised regions, which serve as the protrusion portions while maintaining compositional continuity.

In one example, the top surface of the protrusion portion includes a textured surface comprising either a corrugated or an irregular pattern. The texture may be formed during planarization layer patterning or subsequent processing, and may consist of random surface roughness or periodic undulations. In some cases, the top surface exhibits a non-flat topology characterized by continuous ridges, valleys, or peaks that vary in height and spacing.

In certain embodiments, the top surface of the protrusion portion exhibits surface roughness having a patterned or irregular topography. The term “topography” refers to the three-dimensional geometric features of the surface, including spatial variations in height, contour, and slope. The topography may be periodic or non-periodic and may include continuous or discontinuous features such as ridges, valleys, undulations, or random asperities. The surface roughness may be introduced by patterning techniques applied to the planarization layer or by subsequent texturing processes. Such patterned or irregular topography can influence both the optical and deposition characteristics of overlying layers, including light extraction, angular emission, and thin film uniformity.

In such embodiments, the first electrode 121 may conform to the shape of the corrugated surface of the protrusion portion. The electrode may be deposited by methods such as sputtering or evaporation, allowing it to follow the surface profile of the textured or irregular topography without breaking continuity.

The presence of surface roughness on the top surface of the protrusion portion can enhance angular light distribution. In particular, the corrugated or irregular surface pattern can scatter emitted light in various directions, increasing the effective viewing angle of the display. This effect is especially advantageous in displays that require wide-angle luminance consistency.

In a further embodiment, the top surface of the bank is substantially flat and extends laterally beyond the emission area defined by the protrusion portion. This extended flat region may serve to block light leakage, reduce reflections, and provide a continuous support surface for overlying encapsulation films or touch electrode structures.

According to another aspect of the present disclosure, there is provided a display device. The display device includes a planarization layer disposed above a substrate and including a protrusion portion, an anode disposed on a top surface and a side surface of the protrusion portion, a bank disposed to cover the anode except for the top surface of the protrusion portion, an organic layer disposed on the anode exposed by the bank and a cathode disposed on the organic layer, the bank may have a height which is equal to or lower than a height of the top surface of the protrusion portion.

The planarization layer may includes a bottom layer disposed in an emission area and a non-emission area and the protrusion portion disposed on the bottom layer and corresponding to the emission area.

Top surfaces of the protrusion portion and the bank may be flat and free of a step.

The height may refer to a distance from a reference layer to a top surface of the bank or the protrusion portion.

The top surface of the protrusion portion may correspond to a protrusion area and the side surface of the protrusion portion may extend from the top surface of the protrusion portion.

The anode may be disposed on a part of the top surface of the bottom layer of the planarization layer and the top surface and the side surface of the protrusion portion.

The anode may include a first area disposed in a part of the top surface of the bottom layer, a second area extending from the first area to be disposed on the side surface of the protrusion portion and a third area extending from the second area to be disposed in the protrusion area.

The third area of the anode may correspond to the top surface of the protrusion portion.

The bank may cover the first area and the second area of the anode and may expose the third area of the anode.

The bank may include a top surface, a side surface, and a bottom surface.

The top surface of the bank may be parallel to the top surface of the protrusion portion.

The top surface of the bank may correspond to the non-emission area and the side surface and the bottom surface of the bank may correspond to the non-emission area.

The side surface of the bank may extend from the top surface of the bank and may correspond to the side surface of the protrusion portion.

The bottom surface of the bank may correspond to a surface that is in contact with the anode in the first area of the anode.

The protrusion area may have a width and an area which are smaller than those of the emission area defined by the bank and the third area of the anode may be exposed by the emission area.

The organic layer may be disposed on the bank and a top surface of the third area of the anode.

The display device may further comprise an encapsulation unit disposed above the cathode, a touch sensor layer disposed above the encapsulation unit and a black matrix and a color filter layer disposed above the encapsulation unit.

The top surface of the protrusion portion may have a concave and convex uneven structure and the anode, the organic layer, and the cathode may have a concave and convex uneven structure corresponding to a shape of the top surface of the protrusion portion.

According to another aspect of the present disclosure, there is provided a display device. The display device includes a planarization layer disposed above a substrate, a protrusion portion disposed on the planarization layer and protruding to correspond to an emission area, an anode disposed on a part of a top surface of the planarization layer and a top surface and a side surface of the protrusion portion, a bank disposed so as to cover the anode except for the top surface of the protrusion portion; an organic layer disposed on the anode exposed by the bank and a cathode disposed on the organic layer, the bank may have a height which is equal to or lower than a height of the top surface of the protrusion portion.

Top surfaces of the protrusion portion and the bank may be flat without having a step.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a planarization layer disposed on a substrate and including a protrusion portion having a top surface and a side surface extending from the top surface;
an anode disposed on the top surface and the side surface of the protrusion portion;
a bank disposed to cover the anode except for the top surface of the protrusion portion;
an organic layer disposed on the anode exposed by the bank; and
a cathode disposed on the organic layer,
wherein the bank has a height that is equal to or lower than a height of the top surface of the protrusion portion.

2. The display device according to claim 1, wherein the planarization layer includes:
a bottom layer disposed in an emission area and a non-emission area; and
the protrusion portion disposed on the bottom layer and corresponding to the emission area.

3. The display device according to claim 1, wherein top surfaces of the protrusion portion and the bank are flat and free of a step.

4. The display device according to claim 1, wherein the height refers to a distance from a reference layer to a top surface of the bank or the protrusion portion.

5. The display device according to claim 2, wherein the top surface of the protrusion portion corresponds to a protrusion area and the side surface of the protrusion portion extends from the top surface of the protrusion portion.

6. The display device according to claim 2, wherein the anode is disposed on a part of the top surface of the bottom layer of the planarization layer and the top surface and the side surface of the protrusion portion.

7. The display device according to claim 5, wherein the anode includes:
a first area disposed in a part of the top surface of the bottom layer;
a second area extending from the first area to be disposed on the side surface of the protrusion portion; and
a third area extending from the second area to be disposed in the protrusion area.

8. The display device according to claim 7, wherein the third area of the anode corresponds to the top surface of the protrusion portion.

9. The display device according to claim 7, wherein the bank covers the first area and the second area of the anode and exposes the third area of the anode.

10. The display device according to claim 7, wherein the bank includes a top surface, a side surface, and a bottom surface.

11. The display device according to claim 10, wherein the top surface of the bank is parallel to the top surface of the protrusion portion.

12. The display device according to claim 10, wherein the top surface of the bank corresponds to the non-emission area and the side surface and the bottom surface of the bank correspond to the non-emission area.

13. The display device according to claim 10, wherein the side surface of the bank extends from the top surface of the bank to the side surface and corresponds to the side surface of the protrusion portion.

14. The display device according to claim 10, wherein the bottom surface of the bank corresponds to a surface that is in contact with the anode in the first area of the anode.

15. The display device according to claim 7, wherein the protrusion area has a width and an area which are smaller than those of the emission area defined by the bank and the third area of the anode is exposed by the emission area.

16. The display device according to claim 7, wherein the organic layer is disposed on the bank and a top surface of the third area of the anode.

17. The display device according to claim 1, further comprising:
an encapsulation unit disposed on the cathode;
a touch sensor layer disposed on the encapsulation unit; and
a black matrix and a color filter layer disposed on the encapsulation unit.

18. The display device according to claim 1, wherein the top surface of the protrusion portion has a concave and convex uneven structure and the anode, the organic layer, and the cathode have a concave and convex uneven structure corresponding to a shape of the top surface of the protrusion portion.

19. A display device comprising:
a planarization layer disposed on a substrate;
a protrusion portion disposed on the planarization layer and protruding to correspond to an emission area;
an anode disposed on a part of a top surface of the planarization layer and a top surface and a side surface of the protrusion portion;
a bank disposed so as to cover the anode except for the top surface of the protrusion portion;
an organic layer disposed on the anode exposed by the bank; and
a cathode disposed on the organic layer,
wherein the bank has a height which is equal to or lower than a height of the top surface of the protrusion portion.

20. The display device according to claim 19, wherein top surfaces of the protrusion portion and the bank are flat without having a step.

21. A display device comprising:
a substrate;
a planarization layer disposed on the substrate;
a protrusion portion disposed on the planarization layer, the protrusion portion having a first side surface, a second side surface opposite the first side surface, and a top surface between the first and second side surfaces;
a first electrode extending continuously along the top surface, the first side surface, and the second side surface of the protrusion portion;
a bank adjacent to the protrusion portion, the bank having a top surface;
an organic layer disposed on the first electrode; and
a second electrode disposed on the organic layer,
wherein the top surface of the bank is substantially co-planar with the top surface of the protrusion portion.

22. The display device according to claim 21, wherein the protrusion portion is integrally formed with the planarization layer from the same material.

23. The display device according to claim 21, wherein the bank defines a lateral opening corresponding to an emission area above the protrusion portion.

24. The display apparatus of claim 21, wherein the bank covers only a portion of the side surfaces of the first electrode, leaving the top surface of the protrusion portion exposed.

25. A display device comprising:
a substrate;
a planarization layer disposed on the substrate;
a protrusion portion disposed on the planarization layer, the protrusion portion having a first side surface, a second side surface opposite the first side surface, and a top surface between the first and second side surfaces;
a first electrode extending continuously along the top surface, the first side surface, and the second side surface of the protrusion portion;
a bank adjacent to the protrusion portion, the bank having a top surface;
an organic layer disposed on the first electrode; and
a second electrode disposed on the organic layer,
wherein the top surface of the bank is non-coplanar and lies below the top surface of the protrusion portion.

26. The display device according to claim 24, wherein the protrusion portion is integrally formed with the planarization layer from the same material.

27. The display device according to claim 24, wherein the top surface of the protrusion portion includes a textured surface comprising either a corrugated or an irregular pattern.

28. The display device according to claim 27, wherein the first electrode conforms to the corrugated pattern of the top surface of the protrusion portion.

29. The display device according to claim 27, wherein the surface roughness on the protrusion portion increases light scattering toward oblique viewing angles.

30. The display device according to claim 25, wherein the top surface of the bank is substantially flat and extends laterally beyond an emission area.
